(19) United States
(12) Patent Application Publication
(10) Pub. No.: US 2004/0108534 A1
(43) Pub. Date: Jun. 10, 2004

(54) Semiconductor device and manufacturing method for the same

(75) Inventors: Takaaki Tsunomura, Hyogo (JP); Masahiko Takeuchi, Hyogo (JP)

Correspondence Address: McDermott, Will & Emery, 600 13th Street, N.W., Washington, DC, 20005-3096, US

(73) Assignee: Renesas Technology Corp.

(21) Appl. No.: 10/455,325

(22) Filed: Jun. 6, 2003

(30) Foreign Application Priority Data
Dec. 4, 2002 (JP) 2002-352527(P)

(51) Int. Cl. H01L 27/108

(52) U.S. Cl. 257/300

(57) ABSTRACT

A storage node in a capacitor of a semiconductor device is formed of: an inner conductor in a columnar form having bottom, side and top surfaces; and an outer conductor, located on the bottom (between the bottom surface and the semiconductor substrate), side and top surfaces of the inner conductor, having a different material from that of the inner conductor. The outer conductor is formed of a metal film such as of Ru having a film thickness of about 40 nm to 80 nm. The inner conductor is formed of a film, such as a TiN film, a TaN film, a WN film or the like, having a high adhesion to the metal film such as of Ru. With this configuration, it is possible to provide a semiconductor device provided with a capacitor of which the capacitance is obtained.

### BACKGROUND OF THE INVENTION

1. Field of the Invention

The present invention relates to a semiconductor device and a manufacturing method for the same, and more particularly to a semiconductor device including an MIM (Metal Insulator Metal) capacitor which forms a semiconductor memory, and a manufacturing method for the same.

2. Description of the Background Art

A charge is stored as data in a predetermined capacitor in a semiconductor device, such as a memory device or a device including a memory. An MIM capacitor has been proposed, such as a capacitor. Capacitance of a MIM capacitor is increased, because depletion is not occurred in the electrode of an MIM capacitor.

Therefore, an example of a manufacturing method for an MIM capacitor portion (first prior art) is described below. First, an opening is formed in an interlayer insulating film having a predetermined film thickness formed on a semiconductor substrate. A predetermined metal film, such as of Ru, which becomes a storage node, is formed over the interlayer insulating film so as to fill in the opening.

Next, the metal film located on the upper surface of the interlayer insulating film is removed so that the metal film remains within the opening. After that, the interlayer insulating film is removed so that the metal film is exposed. A dielectric film, such as of Ta₂O₅, is formed so as to cover the exposed metal film.

Next, a predetermined metal film, such as of Ru, which becomes a cell plate, is formed so as to cover the dielectric film. As described above, an MIM capacitor wherein a capacitor dielectric film, such as of Ta₂O₅, is interposed between the storage node, such as of Ru, and the cell plate.

Next, another example of a manufacturing method for an MIM capacitor portion is described as the second prior art (U.S. Pat. No. 6,037,206). A predetermined metal film that becomes a storage node having a predetermined film thickness is formed on a semiconductor substrate. A resist pattern is formed on the metal film. Etching is carried out on the metal film using the resist pattern as a mask.

A plate in the form of walls resulting from the reaction between the resist and the metal film at the time of etching is formed on the side surfaces of the metal film. A conductive layer is formed on the metal film so as to cover the plate in the form of walls. A storage node is formed of the metal film and the conductive layer. A capacitor dielectric film, such as of Ta₂O₅, is formed on the storage node.

A conductive layer that becomes a cell plate is formed on the capacitor dielectric film. As described above, an MIM capacitor is formed wherein a capacitor dielectric film, such as of Ta₂O₅, is interposed between the storage node and the cell plate.

The following problems arise, however, in semiconductor devices provided with MIM capacitors according to the prior arts. A technique for increasing the height of an MIM capacitor is adopted as one of the techniques for securing the capacitance of the MIM capacitor within a limited region in accordance with the miniaturization and increase in integration of semiconductor devices.

In the two above described manufacturing methods for semiconductor devices, it is necessary to increase the thickness of the metal film that is formed for a storage node in order to increase the height of the MIM capacitors.

In the case of the first prior art, for example, an interlayer insulating film having a film thickness of from approximately 1000 nm to 1500 nm is formed and a Ru film having a film thickness of from approximately 80 nm to 120 nm is formed on the interlayer insulating film so that a storage node is formed within the opening.

In the case that the film thickness of the Ru film is increased to from approximately several hundred nanometers to one thousand plus several hundred nanometers, however, a problem arises wherein the Ru film easily peels off of the base portion. Therefore, there is a lower limit to the film thickness of the Ru film that is formed that limits the height of the MIM capacitor and a problem arises wherein a sufficient capacitance of the MIM capacitor cannot be secured.

In addition, in the same manner according to the second prior art, in the case that the film thickness of the Ru film is increased to from approximately several hundred nanometers to one thousand plus several hundred nanometers, the Ru film easily peels off of the base portion and a problem arises wherein a sufficient capacitance of the MIM capacitor cannot be secured.

### SUMMARY OF THE INVENTION

The present invention is provided to solve the above described problems, and an object of the present invention is to provide a semiconductor device with a capacitor of which the capacitance is secured. Another object of the present invention is to provide a manufacturing method for such a semiconductor device.

A semiconductor device according to the present invention includes a capacitor with a dielectric film interposed between a first electrode and a second electrode, wherein the first electrode includes an inner conductor and an outer conductor. The inner conductor is formed on the main surface of a semiconductor substrate and has bottom, side and top surfaces. The outer conductor is formed on the side and top surfaces of the inner conductor, respectively, and has a different material from that of the inner conductor.

Conventionally, increase in the height of the first electrode using only an outer conductive layer which functions as the outer conductor is limited due to the peeling off of this outer conductive layer, while in the present semiconductor device, the desired height of the first electrode is secured by the inner conductor wherein the outer conductor is formed on the side and top surfaces of this inner conductor. Thereby, the height of the first electrode can be increased without increasing the thickness of the outer conductive layer, so that the capacitance of the capacitor formed between the first electrode and the second electrode can be secured.

One manufacturing methods for a semiconductor device according to the present invention includes the following steps. A first electrode including an inner conductor and an outer conductor is formed. A second conductor on the first electrode with a dielectric film interposed therebetween. The step of forming this first electrode includes the following steps. An insulating film is formed on a semiconductor substrate. An opening having a predetermined depth is formed in the insulating film. An outer first conductive layer which functions as the outer conductor is formed so as to cover the bottom and side surfaces of the opening. An inner conductive layer, which has a different material from that of the outer first conductive layer functions as the inner conductor, is formed on the outer first conductive layer within the opening. The top surface of the inner conductive layer is covered with the outer second conductive layer which has substantially the same material as the outer first conductive layer and functions as the outer conductor. The insulating layer is removed and the surfaces of the outer first conductive layer and of the outer second conductive layer are exposed.

According to this manufacturing method, first, the outer first conductive layer is formed so as to cover the bottom and side surfaces of the opening provided in the insulating film, and the inner conductive layer having a material different from that of the outer first conductive layer is formed on this outer first conductive layer. The outer second conductive layer is formed on the top surface of this inner conductive layer. Thereby, the height of the first electrode can be increased without increasing the thickness of the outer conductive layer. As a result, a semiconductor device is formed wherein the capacitance between the first electrode and the second electrode is secured.

Another manufacturing method for a semiconductor device according to the present invention includes the following steps. A first electrode including an inner conductor and an outer conductor is formed. A second electrode is formed on the first electrode with a dielectric film interposed therebetween. The step of forming this first electrode includes the following steps. An inner conductor having an inner conductive layer having side and top surfaces is formed on a semiconductor substrate. An outer conductive layer, which has a different material from that of the inner conductive layer and functions as an outer conductor, is formed so as to cover the inner conductor.

According to this manufacturing method, first, the inner conductor is formed, which has the inner conductive layer having side and top surfaces. The outer conductive layer, which has a different material from that of the inner conductive layer and functions as an outer conductor, is formed so as to cover the inner conductor. Thereby, the height of the first electrode can be increased without increasing the thickness of the outer conductive layer. As a result, a semiconductor device is formed wherein the capacitance between the first electrode and the second electrode is secured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of a semiconductor device according to a first embodiment of the present invention;

FIG. 2 is a cross sectional view showing one step of a manufacturing method for a semiconductor device according to a second embodiment of the present invention;

FIG. 3 is a cross sectional view showing a step carried out after the step shown in FIG. 2 according to the second embodiment;

FIG. 4 is a cross sectional view showing a step carried out after the step shown in FIG. 3 according to the second embodiment;

FIG. 5 is a cross sectional view showing a step carried out after the step shown in FIG. 4 according to the second embodiment;

FIG. 6 is a cross sectional view showing a step carried out after the step shown in FIG. 5 according to the second embodiment;

FIG. 7 is a cross sectional view showing a step carried out after the step shown in FIG. 6 according to the second embodiment;

FIG. 8 is a cross sectional view showing a step carried out after the step shown in FIG. 7 according to the second embodiment;

FIG. 9 is a cross sectional view showing a step carried out after the step shown in FIG. 8 according to the second embodiment;

FIG. 10 is a cross sectional view showing a step carried out after the step shown in FIG. 9 according to the second embodiment;

FIG. 11 is a cross sectional view showing a step carried out after the step shown in FIG. 10 according to the second embodiment;

FIG. 12 is a cross sectional view showing a step carried out after the step shown in FIG. 11 according to the second embodiment;

FIG. 13 is a cross sectional view showing a step carried out after the step shown in FIG. 12 according to the second embodiment;

FIG. 14 is a cross sectional view for describing the effects of the semiconductor device according to the second embodiment;

FIG. 15 is a cross sectional view showing one step of a manufacturing method for a semiconductor device according to a third embodiment of the present invention;

FIG. 16 is a cross sectional view showing a step carried out after the step shown in FIG. 15 according to the third embodiment;

FIG. 17 is a cross sectional view showing a step carried out after the step shown in FIG. 16 according to the third embodiment;

FIG. 18 is a cross sectional view showing a semiconductor device according to a fourth embodiment of the present invention;

FIG. 19 is a cross sectional view showing one step of a manufacturing method for a semiconductor device according to a fifth embodiment of the present invention;

FIG. 20 is a cross sectional view showing a step carried out after the step shown in FIG. 19 according to the fifth embodiment;

FIG. 21 is a cross sectional view showing a step carried out after the step shown in FIG. 20 according to the fifth embodiment;

FIG. 22 is a cross sectional view showing a step carried out after the step shown in FIG. 21 according to the fifth embodiment;

FIG. 23 is a cross sectional view showing a step carried out after the step shown in FIG. 22 according to the fifth embodiment;

FIG. 24 is a cross sectional view showing a step carried out after the step shown in FIG. 23 according to the fifth embodiment;

FIG. 25 is a cross sectional view showing a step carried out after the step shown in FIG. 24 according to the fifth embodiment;

FIG. 26 is a cross sectional view showing a step carried out after the step shown in FIG. 25 according to the fifth embodiment;

FIG. 27 is a cross sectional view showing a step carried out after the step shown in FIG. 26 according to the fifth embodiment;

FIG. 28 is a cross sectional view showing one step of a manufacturing method for a semiconductor device according to a sixth embodiment of the present invention;

FIG. 29 is a cross sectional view showing a semiconductor device according to a seventh embodiment of the present invention;

FIG. 30 is a cross sectional view showing one step of a manufacturing method for a semiconductor device according to an eighth embodiment of the present invention;

FIG. 31 is a cross sectional view showing a step carried out after the step shown in FIG. 30 according to the eighth embodiment;

FIG. 32 is a cross sectional view showing a step carried out after the step shown in FIG. 31 according to the eighth embodiment;

FIG. 33 is a cross sectional view showing a step carried out after the step shown in FIG. 32 according to the eighth embodiment;

FIG. 34 is a cross sectional view showing a step carried out after the step shown in FIG. 33 according to the eighth embodiment;

FIG. 35 is a cross sectional view showing a step carried out after the step shown in FIG. 34 according to the eighth embodiment;

FIG. 36 is a cross sectional view showing a step carried out after the step shown in FIG. 35 according to the eighth embodiment;

FIG. 37 is a cross sectional view showing a step carried out after the step shown in FIG. 36 according to the eighth embodiment;

FIG. 38 is a cross sectional view showing a step carried out after the step shown in FIG. 37 according to the eighth embodiment;

FIG. 39 is a cross sectional view showing a step carried out after the step shown in FIG. 38 according to the eighth embodiment;

FIG. 40 is a cross sectional view showing a step carried out after the step shown in FIG. 39 according to the eighth embodiment;

FIG. 41 is a cross sectional view showing a step carried out after the step shown in FIG. 40 according to the eighth embodiment;

FIG. 42 is a cross sectional view showing a step carried out after the step shown in FIG. 41 according to the eighth embodiment;

FIG. 43 is a cross sectional view showing a step carried out after the step shown in FIG. 42 according to the eighth embodiment;

FIG. 44 is a cross sectional view showing one step of a manufacturing method for a semiconductor device according to a ninth embodiment of the present invention;

FIG. 45 is a cross sectional view showing a step carried out after the step shown in FIG. 44 according to the ninth embodiment;

FIG. 46 is a cross sectional view showing a step carried out after the step shown in FIG. 45 according to the ninth embodiment;

FIG. 47 is a cross sectional view showing a semiconductor device according to a tenth embodiment of the present invention;

FIG. 48 is a cross sectional view showing one step of a manufacturing method for a semiconductor device according to an eleventh embodiment of the present invention;

FIG. 49 is a cross sectional view showing a step carried out after the step shown in FIG. 48 according to the eleventh embodiment;

FIG. 50 is a cross sectional view showing a step carried out after the step shown in FIG. 49 according to the eleventh embodiment;

FIG. 51 is a cross sectional view showing a step carried out after the step shown in FIG. 50 according to the eleventh embodiment;

FIG. 52 is a cross sectional view showing a step carried out after the step shown in FIG. 51 according to the eleventh embodiment;

FIG. 53 is a cross sectional view showing a step carried out after the step shown in FIG. 52 according to the eleventh embodiment;

FIG. 54 is a cross sectional view showing a step carried out after the step shown in FIG. 53 according to the eleventh embodiment;

FIG. 55 is a cross sectional view showing a step carried out after the step shown in FIG. 54 according to the eleventh embodiment;

FIG. 56 is a cross sectional view showing a step carried out after the step shown in FIG. 55 according to the eleventh embodiment;

FIG. 57 is a cross sectional view showing a step carried out after the step shown in FIG. 56 according to the eleventh embodiment;

FIG. 58 is a cross sectional view showing one step of a manufacturing method for a semiconductor device according to a twelfth embodiment of the present invention;

FIG. 59 is a cross sectional view showing one step of a manufacturing method for a semiconductor device according to a thirteenth embodiment of the present invention;

FIG. 60 is a cross sectional view showing a step carried out after the step shown in FIG. 59 according to the thirteenth embodiment;

FIG. 61 is a cross sectional view showing a step carried out after the step shown in FIG. 60 according to the thirteenth embodiment;

FIG. 62 is a cross sectional view showing a step carried out after the step shown in FIG. 61 according to the thirteenth embodiment;

FIG. 63 is a cross sectional view showing a step carried out after the step shown in FIG. 62 according to the thirteenth embodiment;

FIG. 64 is a cross sectional view showing a step carried out after the step shown in FIG. 63 according to the thirteenth embodiment;

FIG. 65 is a cross sectional view showing a step carried out after the step shown in FIG. 64 according to the thirteenth embodiment;

FIG. 66 is a cross sectional view showing a step carried out after the step shown in FIG. 65 according to the thirteenth embodiment;

FIG. 67 is a cross sectional view showing a step carried out after the step shown in FIG. 66 according to the thirteenth embodiment; and

FIG. 68 is a cross sectional view showing a step carried out after the step shown in FIG. 67 according to the thirteenth embodiment.

### DESCRIPTION OF THE PREFERRED EMBODIMENTS

### First Embodiment

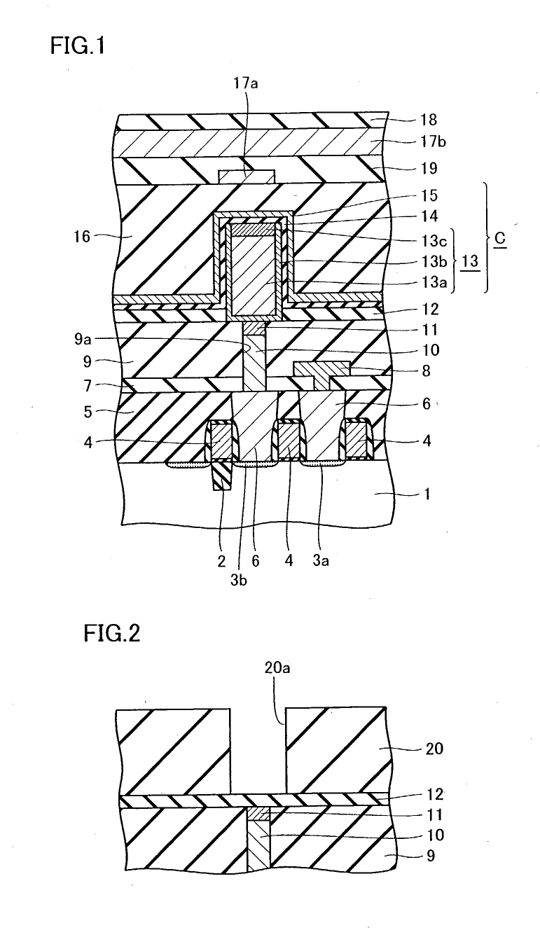

A manufacturing method for a semiconductor device according to a first embodiment of the present invention is described below. As shown in FIG. 1, a memory cell transistor including a gate electrode 4 and source/drain regions 3a and 3b is formed on the main surface of semiconductor substrate 1.

A silicon oxide film 5 is formed on semiconductor substrate 1 so as to cover the memory cell transistor. Pads 6 made of a predetermined polysilicon film are formed in openings formed in this silicon oxide film 5 so as to be electrically connected to source/drain regions 3a and 3b.

A silicon oxide film 7 is additionally formed on silicon oxide film 5. A bit line 8 electrically connected to one of pads 6 is formed on this silicon oxide film 7. A silicon oxide film 9 is additionally formed so as to cover this bit line 8.

A storage node contact hole 9a is formed in the above described silicon oxide film 9 so as to expose the surface of the other of pads 6. A plug 10 and a barrier metal 11 are formed within this storage node contact hole 9a.

A storage node 13 is formed on silicon oxide film 9 so as to be electrically connected to plug 10 and barrier metal 11. A silicon nitride film 12 is formed on the portion of silicon oxide film 9 on which storage node 13 is not located. A cell plate 15 is formed on the surface of this storage node 13 with a dielectric film 14, made of Ta₂O₅, interposed therebetween.

Storage node 13, dielectric film 14 and cell plate 15 form a capacitor C. A silicon oxide film 16 is formed above semiconductor substrate 1 so as to cover this capacitor C.

An aluminum wire 17a in the first layer is formed on the above described silicon oxide film 16 and a silicon oxide film 19 is formed so as to cover this aluminum wire 17a.

An aluminum wire 17b in the second layer is formed on the above described silicon oxide film 19. A passivation coating film 18 is formed so as to cover this aluminum wire 17b.

In the present semiconductor device, in particular, storage node 13 in capacitor C is formed of an inner conductor 13a in a columnar form having bottom, side and top surfaces, and of outer conductors 13b and 13c, which are located on the bottom (between the bottom surface and the semiconductor substrate), side and top surfaces of inner conductor 13a and which are made of a material different from that of inner conductor 13a.

Outer conductors 13b and 13c are formed of a metal film, such as of Ru, having a film thickness of from approximately 40 nm to 80 nm. Inner conductor 13a is formed of a film having a high adhesion to the metal film, such as of Ru. A TiN film, a TaN film or a WN film, for example, is used as the film having a high adhesion to Ru, or the like.

Outer conductors 13b and 13c made of a metal film, such as a Ru film, are formed on the bottom, side and top surfaces of inner conductor 13a in storage node 13 of the above described semiconductor device.

Thereby, in the present semiconductor device, the desired height of storage node 13 is provided by inner conductor 13a, having a high adhesion to Ru, wherein outer conductors 13b and 13c, made of Ru, are formed on the side and top surfaces of this inner conductor 13a, in contrast to the prior art wherein increase in the height of the storage node by means of increase in the thickness of the metal film, such as a Ru film, is limited due to the peeling off of the Ru film.

As a result, the height of storage node 13 can be increased without increasing the thickness of the metal film, such as of Ru, so that the capacitance of capacitor C can be secured.

In addition, a comparatively thin Ru film is formed on the surfaces of inner conductor 13a as outer conductors 13b and 13c and, thereby, outer conductors 13b and 13c can be prevented from peeling off and the yield of semiconductor devices is increased.

Furthermore, a comparatively thin Ru film is formed as outer conductors 13b and 13c and, thereby, increase in the production cost due to the usage of Ru film, which is expensive, can be avoided.

### Second Embodiment

An example of a manufacturing method for the semiconductor device described in the first embodiment is described below as a second embodiment of the present invention.

First, the memory cell transistor that includes element isolation insulating film 2, gate electrode 4 and source/drain regions 3a and 3b as well as pads 6, bit line 8, plug 10 and barrier metal 11 located beneath capacitor C shown in FIG. 1 are formed according to a generally known manufacturing method.

Next, as shown in FIG. 2, silicon nitride film 12 is formed on silicon oxide film 9. Silicon oxide film 20 having a film thickness of from approximately 1000 nm to 1500 nm is formed on this silicon nitride film 12.

A predetermined resist pattern (not shown) is formed on the above described silicon oxide film 20. Anisotropic etching is carried out on silicon oxide film 20 using this resist pattern as a mask and, thereby, opening 20a, through which the surface of silicon nitride film 12 is exposed, is formed.

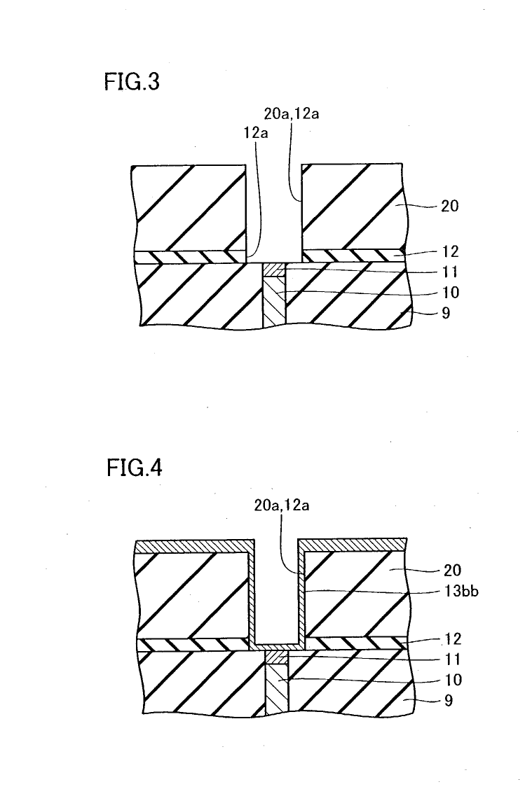

Next, as shown in FIG. 3, further anisotropic etching is carried out on exposed silicon nitride film 12 and, thereby, opening 20a, 12a, through which the surface of barrier metal 11 is exposed, is formed.

Next, as shown in FIG. 4, an outer conductive layer 13bb, which becomes the outer conductor of a Ru film, is formed on the surface of silicon oxide film 20, including on the bottom and side surfaces of the above described opening 20a, 12a.

Next, as shown in FIG. 5, an inner conductive layer 13aa, which becomes the inner conductor, is formed on the outer conductive layer 13bb so as to fill in opening 20a, 12a. A TiN film, a TaN film, or a WN film, for example, having a high adhesion to the Ru film is formed as inner conductive layer 13aa.

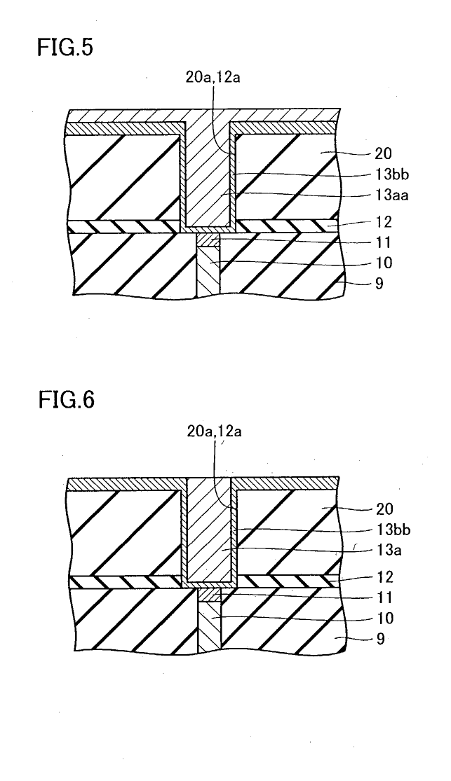

Next, as shown in FIG. 6, dry etching is carried out using a chlorine-based gas in case of a TiN film and a TaN film or a fluorine-based gas in case of a WN film and, thereby, inner conductive layer 13aa located on the top surface of silicon oxide film 20 is removed so that inner conductive layer 13aa remains within opening 20a, 12a.

In addition, at this time a CMP (Chemical Mechanical Polishing) process may be carried out using ammonia-based slurry. Thereby, inner conductor 13a is formed.

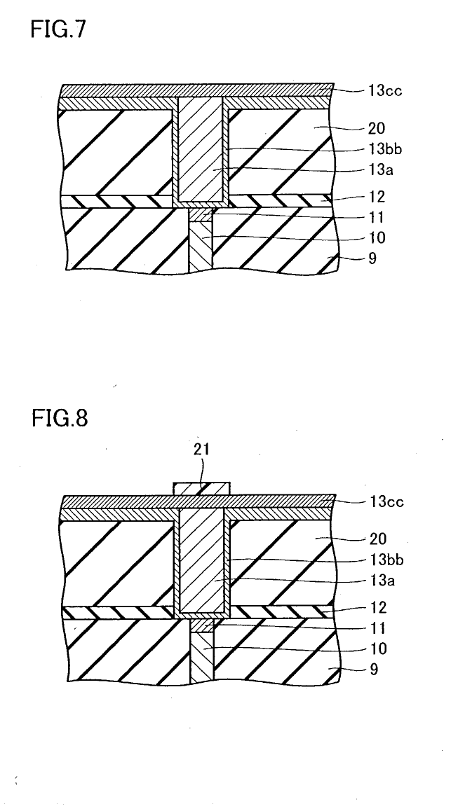

Next, as shown in FIG. 7, outer conductive layer 13cc made of Ru, which becomes the outer conductor, is formed above semiconductor substrate 1. Next, as shown in FIG. 8, a resist pattern 21 is formed on this outer conductive layer 13cc.

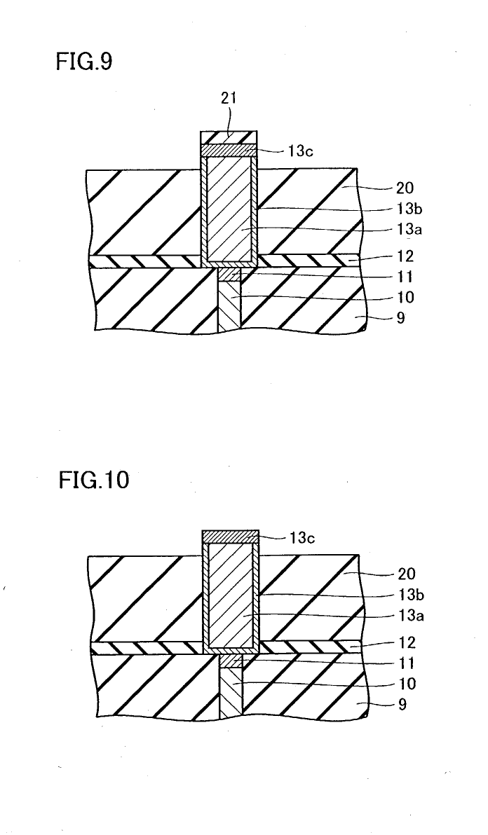

Dry etching using an oxygen-based gas is carried out utilizing the above described resist pattern 21 as a mask and, thereby, the portions of outer conductive layers 13cc and 13bb located above the top surface of silicon oxide film 20 are removed, as shown in FIG. 9.

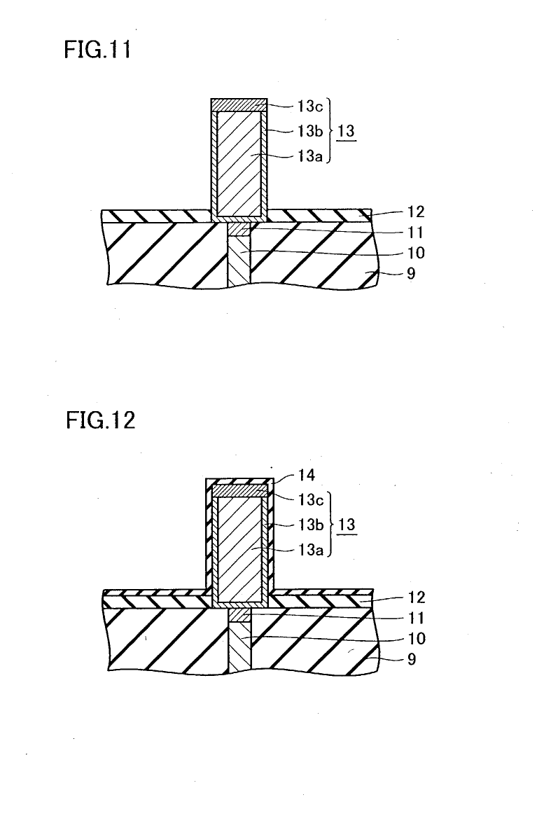

Next, as shown in FIG. 10, resist pattern 21 is removed. After that, as shown in FIG. 11, wet etching is carried out using buffered hydrofluoric acid (BHF) and, thereby, silicon oxide film 20 is removed.

Thereby, storage node 13 is formed of inner conductor 13a and outer conductors 13b and 13c. Next, as shown in FIG. 12, dielectric film 14, such as of Ta₂O₅ having a film thickness of from approximately 5 nm to 15 nm, is formed on the surface of storage node 13.

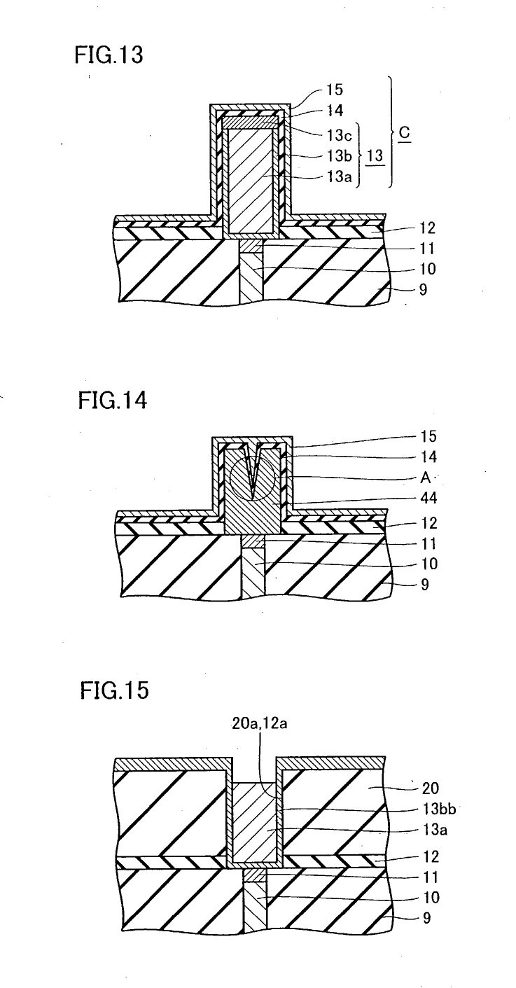

Next, as shown in FIG. 13, cell plate 15, such as of Ru having a film thickness of from approximately 40 nm to 80 nm, is formed on dielectric film 14. Thereby, capacitor C is formed of storage node 13, dielectric film 14 and cell plate 15.

After that, as shown in FIG. 1, silicon oxide film 16 is formed above semiconductor substrate 1 so as to cover capacitor C. Aluminum wire 17a of the first layer is formed on this silicon oxide film 16. Silicon oxide film 19 is formed so as to cover this aluminum wire 17a.

Aluminum wire 17b of the second layer is formed on the above described silicon oxide film 19. Passivation coating film 18 is formed so as to cover this aluminum wire 17b. The semiconductor device provided with capacitor C is completed in the above described manner.

According to the above described manufacturing method for a semiconductor device, outer conductor 13b, made of Ru, or the like, is formed on the bottom and side surfaces of the opening formed in silicon oxide film 20, having a predetermined thickness. Then, inner conductor 13a, having a high adhesion to Ru, is formed so as to fill in this opening. Furthermore, outer conductor 13c, made of Ru, or the like, is formed so as to cover this inner conductor 13a.

Thereby, in the present semiconductor device, the desired height of storage node 13 is provided by inner conductor 13a, having a high adhesion to Ru, wherein outer conductors 13b and 13c, made of Ru, are formed on the side and top surfaces of this inner conductor 13a, in contrast to the prior art wherein increase in the height of the storage node by means of increase in the thickness of the metal film, such as of Ru, is limited due to the peeling off of the Ru film.

As a result, the height of storage node 13 can be increased without increasing the thickness of the metal film, such as of Ru, so that the capacitance of capacitor C can be secured.

In addition, a comparatively thin Ru film is formed on the surfaces of inner conductor 13a as outer conductor layer 13bb and, thereby, outer conductor 13b can be prevented from peeling off and the yield of semiconductor devices is increased.

Furthermore, a comparatively thin Ru film is formed as outer conductor 13b and, thereby, increase in the production cost due to the usage of Ru film, which is expensive, can be avoided.

In addition, as shown in FIG. 14, a recess (see frame A) having a comparatively high aspect ratio is easily formed in the top surface portion of storage node 44 in the case wherein storage node 44 is formed by means of filling in the opening.

In the case wherein such a recess is formed, dielectric film 14 does not have a sufficient thickness at the time when dielectric film 14 is formed on storage node 44 and, thereby, current leaks through this portion.

According to the above described manufacturing method, outer conductor 13c is formed so as to cover the top surface of inner conductor 13a after the formation of inner conductor 13a and, therefore, even in the case wherein a recess is formed in inner conductor 13a, this recess is covered with outer conductor 13c so that current leakage can be prevented.

### Third Embodiment

In the above described manufacturing method, an example of a case wherein outer conductor 13c, which covers the top surface of inner conductor 13a of the storage node, is formed by means of patterning using a resist pattern is cited and described. Here, a case is described wherein outer conductor 13c, which covers the top surface of inner conductor 13a, is formed using a so-called damascene method.

First, after the above described step shown in FIG. 5, dry etching is carried out under the condition wherein the etching selection ratio of inner conductive layer 13aa to outer conductive layer 13bb is comparatively high, using, for example, a chlorine-based gas (TiN, TaN) or a fluorine-based gas (WN) and, thereby, inner conductor 13a, of which the top surface is located at a position lower than the position of the top surface of silicon oxide film 20, is formed, as shown in FIG. 15.

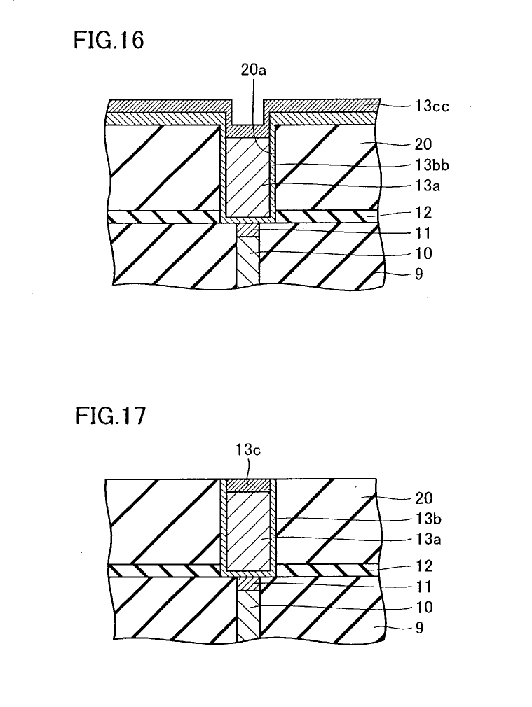

Next, as shown in FIG. 16, outer conductive layer 13cc, made of Ru, is formed so as to cover the top surface of inner conductor 13a within opening 20a. Next, as shown in FIG. 17, a CMP process is carried out and, thereby, the portion of outer conductive layer 13cc located above the top surface of silicon oxide film 20 is removed so that outer conductor 13c is formed on the top surface of inner conductor 13a within opening 20a.

After that, essentially the same steps as the above described steps shown in FIGS. 9 to 13 are followed so as to complete the semiconductor device provided with a capacitor.

According to the above described manufacturing method for a semiconductor device, the following effects are gained in addition to the effects gained according to the above described manufacturing method.

That is to say, the portion of the outer conductive layer that becomes the outer conductor located within the opening remains after the CMP process is carried out so that the outer conductor is formed and, therefore, a photomechanical process for forming outer conductor 13c becomes unnecessary and the number of steps can be reduced.

### Fourth Embodiment

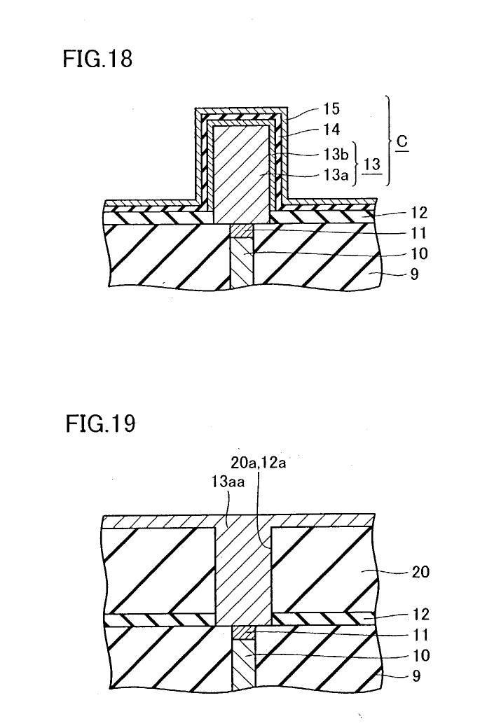

The semiconductor device according to a fourth embodiment of the present invention is described below. As shown in FIG. 18, storage node 13 of capacitor C in the present semiconductor device is formed of inner conductor 13a in a columnar form having side and top surfaces and of outer conductor 13b that is located on the side and top surfaces of inner conductor 13a and that is made of a material different from that of inner conductor 13a.

Outer conductor 13b is formed of a metal film, such as of Ru having a film thickness of from approximately 40 nm to 80 nm, while inner conductor 13a is formed of a film having a high adhesion to the metal film, such as of Ru. A TiN film, a TaN film or a WN film, for example, is used as the film having a high adhesion to Ru, or the like.

Here, though the structures beneath and above capacitor C are not illustrated in FIG. 18, these portions of the present semiconductor device have essentially the same structures as those shown in FIG. 1.

Outer conductor 13b, made of a metal film such as Ru, is formed on the side and top surfaces of inner conductor 13a in storage node 13 of the above described semiconductor device.

Thereby, in the present semiconductor device, the desired height of storage node 13 is provided by inner conductor 13a, having a high adhesion to Ru, wherein outer conductor 13b, made of Ru, is formed on the side and top surfaces of this inner conductor 13a, in contrast to the prior art wherein increase in the height of the storage node by means of increase in the thickness of the metal film, such as of Ru, is limited due to the peeling off of the Ru film.

As a result, the height of storage node 13 can be increased without increasing the thickness of the metal film, such as of Ru, so that the capacitance of capacitor C can be secured.

In addition, a comparatively thin Ru film is formed on the surfaces of inner conductor 13a as outer conductive layer 13bb, which becomes the outer conductor and, thereby, outer conductor 13b can be prevented from peeling off and the yield of semiconductor devices is increased.

Furthermore, a comparatively thin Ru film is formed as outer conductor 13b and, thereby, increase in the production cost due to the usage of Ru film, which is expensive, can be avoided.

In addition, in the case wherein TiN is utilized as inner conductor 13a, TiN has a higher adhesion to the insulating film in comparison with the case wherein Ru forms outer conductor 13b. In this case, the bottom surface of inner conductor 13a makes direct contact with the insulating film, such as silicon oxide film 9, and, thereby, capacitor C does not easily fall over, thus contributing to an increase in the yield of semiconductor devices.

Furthermore, as described below, in the case wherein TaN is utilized as inner conductor 13a, TaN effectively blocks oxygen and can prevent the diffusion of oxygen into storage node contact holes at the time of the oxidation process to Ta₂O₅ and, thereby, increase in the contact resistance between storage node 13 and plug 10 can be restricted.

In addition, inner conductor 13a effectively blocks oxygen in the above described manner and, therefore, the bottom surface of inner conductor 13a may make direct contact with plug 10 without forming barrier metal 11 within the storage node contact hole.

### Fifth Embodiment

An example of a manufacturing method for the semiconductor device described in the fourth embodiment is described below as a fifth embodiment of the present invention.

First, after the step shown in FIG. 3, inner conductive layer 13aa having a film thickness of from approximately 80 nm to 120 nm is formed on silicon oxide film 20 so as to fill in opening 20a, 12a, as in FIG. 19. A TiN film, a TaN film or a WN film, for example, having a high adhesion to the Ru film is formed as inner conductive layer 13aa.

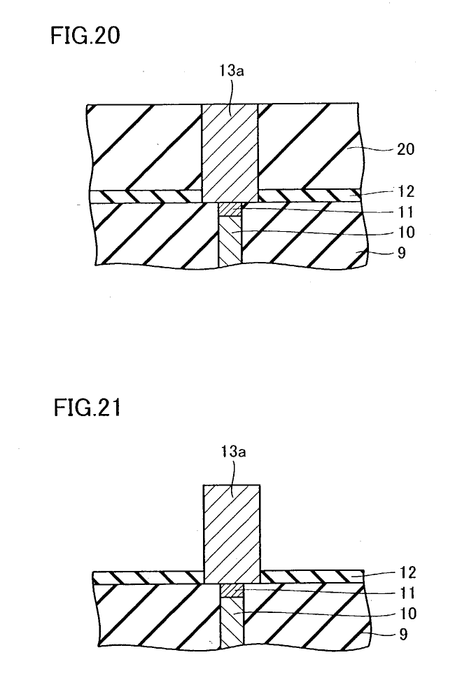

Next, as shown in FIG. 20, dry etching is carried out using, for example, a chlorine-based gas in case of a TiN film and a TaN film or a fluorine-based gas in case of a WN film so as to remove the portion of inner conductive layer 13aa located on the top surface of silicon oxide film 20 and, thereby, inner conductor 13a is formed within opening 20a, 12a. Here, a CMP process may be carried out instead of dry etching in order to form inner conductor 13a.

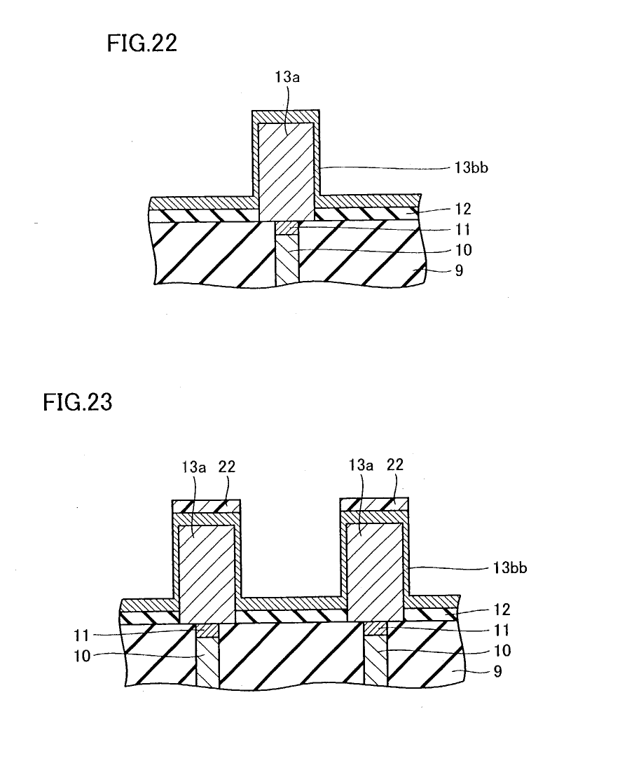

Next, as shown in FIG. 21, wet etching is carried out using buffered hydrofluoric acid (BHF) and, thereby, silicon oxide film 20 is removed. Next, as shown in FIG. 22, outer conductive layer 13bb, which becomes the outer conductor, is formed above semiconductor substrate 1 so as to cover the side and top surfaces of inner conductor 13a.

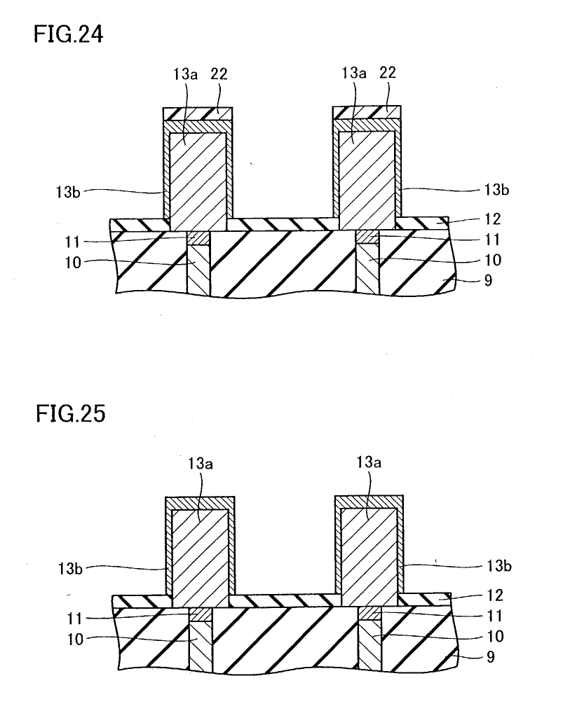

Next, as shown in FIG. 23, a resist pattern 22 is formed so as to cover the portions of outer conductive layer 13bb located on the top surface of inner conductors 13a. Next, as shown in FIG. 24, dry etching using an oxygen-based gas is carried out using resist pattern 22 as a mask and, thereby, the portions of outer conductive layer 13bb located on the top surface of silicon nitride film 12 are removed so that outer conductors 13b are formed on the side and top surfaces of inner conductors 13a.

As a result of this etching process, the portion of outer conductive layer 13bb located between the adjacent storage nodes is removed. After that, as shown in FIG. 25, resist pattern 22 is removed. Thereby, storage nodes 13 are formed of inner conductors 13a and outer conductors 13b.

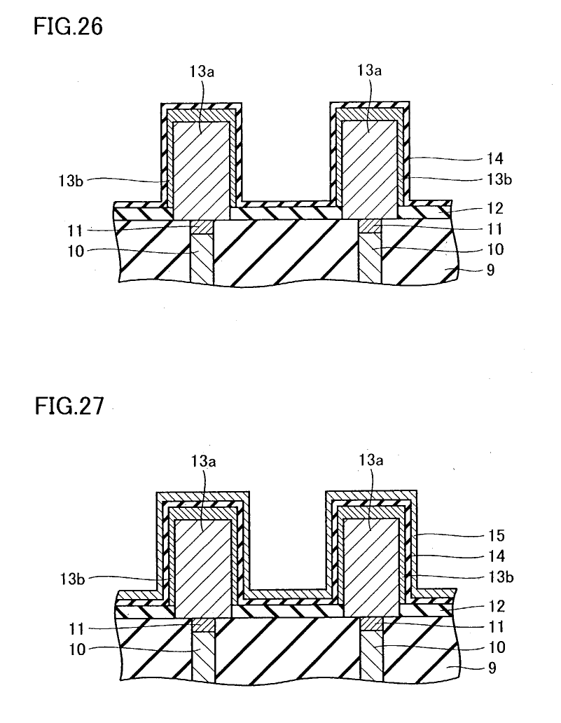

Next, as shown in FIG. 26, dielectric film 14, such as of Ta₂O₅ having a film thickness of from approximately 5 nm to 15 nm, is formed on the surfaces of storage nodes 13. After that, an oxidation process is carried out on the Ta₂O₅ in order to increase the film quality of the Ta₂O₅.

Next, as shown in FIG. 27, cell plate 15, such as a Ru film having a film thickness of from approximately 40 nm to 80 nm is formed on dielectric film 14. Thereby, capacitors C are formed of storage nodes 13, dielectric films 14 and cell plate 15.

After that, as described above, a silicon oxide film that covers capacitors C, predetermined aluminum wires 17a, 17b, and the like, (see FIG. 1), are formed so as to complete the semiconductor device provided with capacitor C.

According to the above described manufacturing method for a semiconductor device, inner conductors 13a, are formed so as to fill in openings 20a, 12a formed in silicon oxide film 20, having a predetermined thickness. Then, outer conductors 13b, such as of Ru, are formed so as cover the side and top surfaces of inner conductors 13a that have been exposed after the removal of silicon oxide film 20.

Thereby, in the present semiconductor device, the desired height of storage node 13 is provided by inner conductor 13a, having a high adhesion to Ru, wherein outer conductors 13b, made of Ru, are formed on the side and top surfaces of this inner conductor 13a, in contrast to the prior art wherein increase in the height of the storage node by means of increase in the thickness of the metal film, such as a Ru film, is limited due to the peeling off of the Ru film.

As a result, the height of storage node 13 can be increased without increasing the thickness of the metal film, such as of Ru, so that the capacitance of capacitor C can be secured.

In addition, a comparatively thin Ru film is formed as outer conductors 13b and, thereby, increase in the production cost due to the usage of Ru film, which is expensive, can be avoided.

Furthermore, in the case wherein TiN is utilized as inner conductor 13a, TiN has a higher adhesion to the insulating film in comparison with the case wherein Ru forms outer conductor 13b. In this case, the bottom surface of inner conductor 13a makes direct contact with the insulating film, such as silicon oxide film 9, and, thereby, capacitor C does not easily fall over, thus contributing to an increase in the yield of semiconductor devices.

In addition, a comparatively thin Ru film is formed on the surfaces of inner conductor 13a as outer conductor layer 13bb and, thereby, outer conductors 13b can be prevented from peeling off and the yield of semiconductor devices is increased.

In addition, in the case wherein Ta₂O₅ is utilized for dielectric film 14, an oxidation process is carried out on the Ta₂O₅ after the formation of the Ta₂O₅ film in order to increase the film quality of the Ta₂O₅.

At this time, in the case wherein Ru is used for outer conductors 13b of storage nodes 13, oxygen diffuses through the Ru portions of the storage nodes and reaches plugs 10 formed within the storage node contact holes wherein plugs 10 become oxidized. As a result, the contact resistance between storage nodes 13 and plugs 10 increases.

In the case wherein TaN is utilized for inner conductors 13a, TaN has excellent characteristics in regard to the blocking of diffusion of oxygen. This semiconductor device is formed so that the bottom surfaces of inner conductors 13a cover the openings of the storage node contact holes.

Thereby, the diffusion of oxygen for the oxidation process is blocked by the storage node 13 portions and, therefore, oxidation is prevented from reaching to plugs 10 within the storage node contact holes. As a result, increase in the contact resistance between storage nodes 13 and plugs 10 can be prevented.

In addition, inner conductors 13a, themselves, effectively block oxygen and, therefore, the formation of barrier metal 11 within the storage node contact holes can be omitted so that the number of steps can be reduced.

In addition, as described above, in the case wherein storage nodes are formed by means of filling in the openings, there may be current leakage due to recesses formed in the top surface portions of the storage nodes.

According to the above described manufacturing method, outer conductors 13b are formed so as to cover the top surfaces of inner conductors 13a after the formation of inner conductors 13a and, therefore, in the case wherein recesses are formed in inner conductors 13a, these recesses are covered with outer conductors 13b so that current leakage can be prevented.

### Sixth Embodiment

An example of a case wherein the portion of outer conductive layer 13bb, which becomes the outer conductor, located between adjacent storage nodes is removed by carrying out a predetermined etching using resist pattern 22 that covers the portion of outer conductive layer 13bb located on the top surface of inner conductor 13a is cited and described in the above described manufacturing method.

Here, another manufacturing method for the semiconductor device described in the fourth embodiment is described by citing an example of a case wherein the above described portion of the outer conductive layer is removed by utilizing the difference in the film thickness in the outer conductive layer resulting from the steps of inner conductor 13a, itself, without forming a resist pattern.

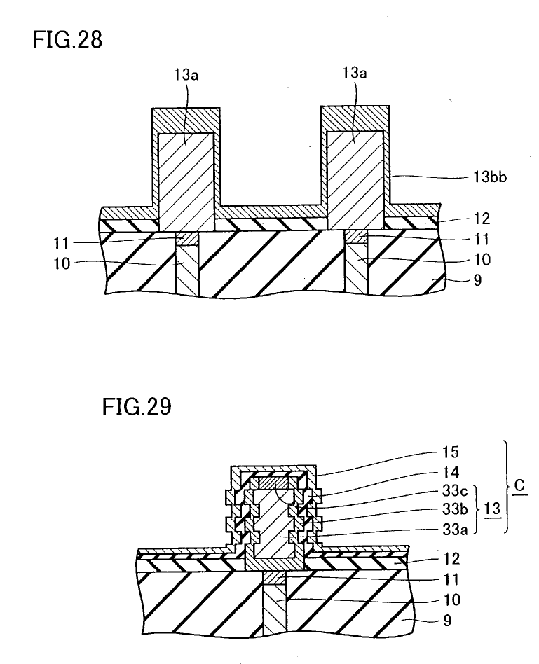

First, after the above described step shown in FIG. 21, outer conductive layer 13bb is formed so as to cover inner conductor 13a, as shown in FIG. 28.

At this time, outer conductive layer 13bb has a comparatively great film thickness in the portions on the top surfaces of inner conductors 13a while outer conductive layer 13bb has a comparatively small film thickness on silicon nitride film 12, located at the base of inner conductors 13a, because of the steps of inner conductors 13a.

That is to say, outer conductive layer 13bb is formed having a poor coverage over inner conductors 13a because of the steps of inner conductors 13a.

After that, etching is carried out on the entire surface of outer conductive layer 13bb and the etching is stopped at the point in time when the portions of outer conductive layer 13bb located on the top surfaces of silicon nitride film 12 have been removed.

Therefore, some portions of outer conductive layer 13bb remain unetched on the top surfaces of inner conductors 13a wherein the portions of outer conductive layer 13bb are thicker than the portions of outer conductive layer 13bb located on the top surfaces of silicon nitride film 12.

Thereby, the portions of outer conductive layer 13bb located between adjacent inner conductors 13a is removed in a self-aligning manner and essentially the same condition as the condition wherein outer conductors 13b are formed on the top surfaces of inner conductors 13a, as shown in the above described FIG. 24, is realized.

After that, essentially the same steps as the above described steps shown in FIGS. 26 and 27 are followed so as to complete the semiconductor device provided with a capacitor.

According to the above described manufacturing method for a semiconductor device, the following effects are gained in addition to the effects gained according to the above described manufacturing method.

That is to say, the portion of outer conductive layer 13bb, which becomes the outer conductor, located between adjacent storage nodes, is removed in a self-aligning manner and, thereby, the photomechanical process for removing this portion becomes unnecessary and the number of steps can be reduced.

### Seventh Embodiment

The semiconductor device according to a seventh embodiment of the present invention is described. As shown in FIG. 29, storage node 13 in capacitor C is formed of inner conductor 33a in a columnar form having side and top surfaces as well as of outer conductors 33b and 33c, made of a material different from that of inner conductor 33a, located on the bottom (between the bottom surface and the semiconductor substrate), side and top surfaces of inner conductor 33a.

Outer conductor 33b is formed of a metal film, such as of Ru having a film thickness of from approximately 40 nm to 80 nm. The surfaces of outer conductor 33b are uneven.

Inner conductor 33a is formed of a film having a high adhesion to the metal film, such as of Ru. A TiN film, a TaN film or a WN film, for example, is used as the film having a high adhesion to Ru, or the like.

Here, though the structures above and below capacitor C are not illustrated in FIG. 29, these portions of the present semiconductor device have essentially the same structures as those shown in FIG. 1.

In the above described semiconductor device, outer conductors 33b and 33c, made of metal films, such as of Ru, are formed on the bottom, side and top surfaces of inner conductor 33a.

Thereby, in the present semiconductor device, the desired height of storage node 13 is provided by inner conductor 33a, having a high adhesion to Ru, wherein outer conductors 33b and 33c, made of Ru, are formed on the side and top surfaces of this inner conductor 33a, in contrast to the prior art wherein increase in the height of the storage node by means of increase in the thickness of the metal film, such as of Ru, is limited due to the peeling off of the Ru film.

As a result, the height of storage node 13 can be increased without increasing the thickness of the metal film, such as of Ru, so that the capacitance of capacitor C can be secured.

Furthermore, the surfaces of outer conductor 33b formed on the side surfaces of inner conductor 33a are uneven and, therefore, the surface area of capacitor C is increased so that the capacitance can be further increased.

In addition, comparatively thin Ru films are formed on the surfaces of inner conductor 33a as outer conductors 33b and 33c and, thereby, outer conductors 33b and 33c can be prevented from peeling off and the yield of semiconductor devices is increased.

Furthermore, comparatively thin Ru films are formed as outer conductors 33b and 33c, and, thereby, increase in the production cost due to the usage of Ru films, which are expensive, can be avoided.

### Eighth Embodiment

An example of a manufacturing method for the semiconductor device described in the seventh embodiment is described below as an eighth embodiment of the present invention.

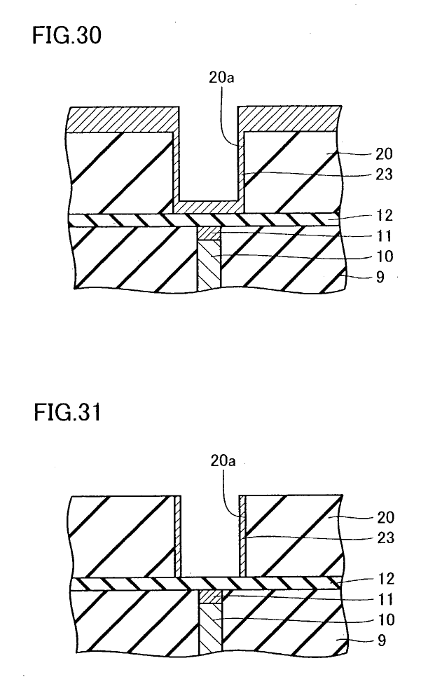

First, after the above described step shown in FIG. 2, an amorphous silicon film 23 having a film thickness of from approximately 20 nm to 30 nm is formed on silicon oxide film 20, including on the bottom and side surfaces of opening 20a, as shown in FIG. 30.

Next, as shown in FIG. 31, etching is carried out on the entire surface of amorphous silicon film 23 and, thereby, the portions of amorphous silicon film 23 located on the top surface of silicon oxide film 20 and on the bottom surface of opening 20a are removed so that the portion of amorphous silicon film 23 located on the side surfaces of opening 20a remains.

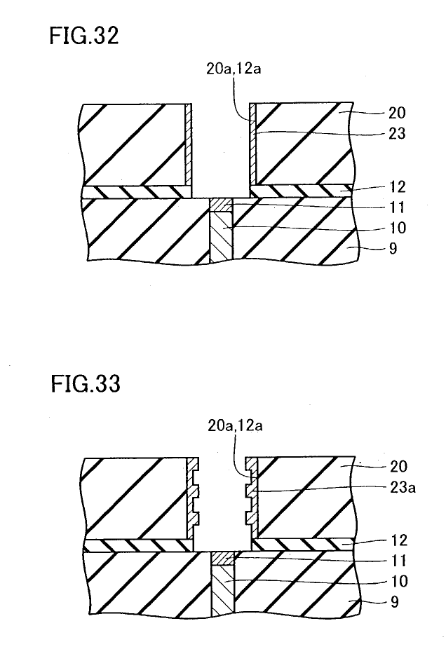

Next, as shown in FIG. 32, silicon nitride film 12 exposed from the bottom surface of opening 20a is removed. Next, as shown in FIG. 33, a surface roughening process is carried out on amorphous silicon film 23 so that amorphous silicon film 23a having a roughened surface is formed.

Concretely, a heat treatment is carried out at a temperature of from approximately 500° C. to 750° C. while an Si₂H₆ gas is made to flow so that this temperature and a high vacuum are maintained and, thereby, unevenness is formed in the surface of amorphous silicon film 23 and amorphous silicon film 23a having a roughened surface is formed.

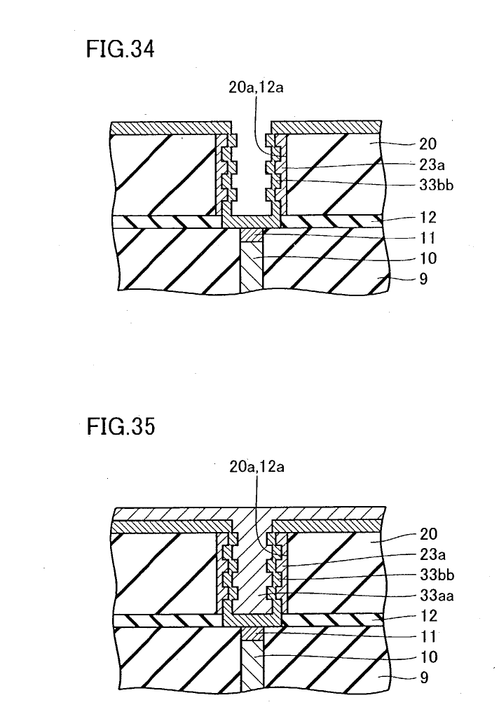

Next, as shown in FIG. 34, an outer conductive layer 33bb made of Ru, which becomes an outer conductor, having a film thickness of from approximately 40 nm to 80 nm is formed on silicon oxide film 20, including on the surface of amorphous silicon film 23a having a roughened surface. At this time, the surface of outer conductive layer 33bb becomes uneven, reflecting the unevenness of the surface of amorphous silicon film 23a having a roughened surface.

Next, as shown in FIG. 35, an inner conductive layer 33aa, which becomes an inner conductor, is formed on outer conductive layer 33bb so as to fill in opening 20a, 12a. A TiN film, a TaN film or a WN film, for example, having a high adhesion to a Ru film, is formed as inner conductive layer 33aa.

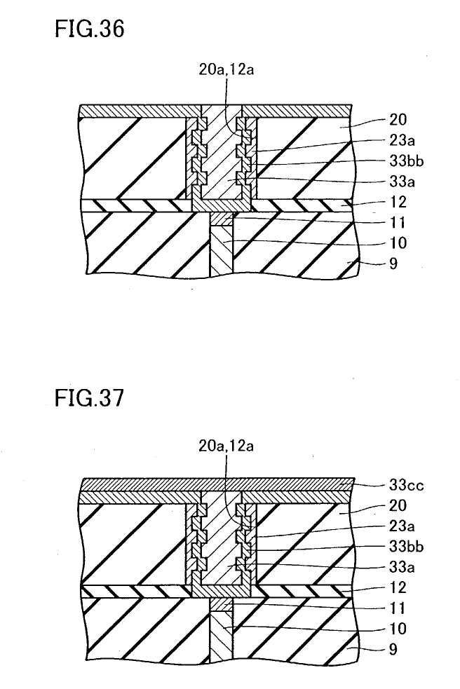

Next, as shown in FIG. 36, dry etching is carried out using a chlorine-based gas in case of a TiN film and a TaN film or a fluorine-based gas in case of a WN film and, thereby, the portion of inner conductive layer 33aa located on the top surface of silicon oxide film 20 is removed so that inner conductor 33a is formed within opening 20a. Here a CMP process may be carried out instead of etching so that inner conductor 33a is formed.

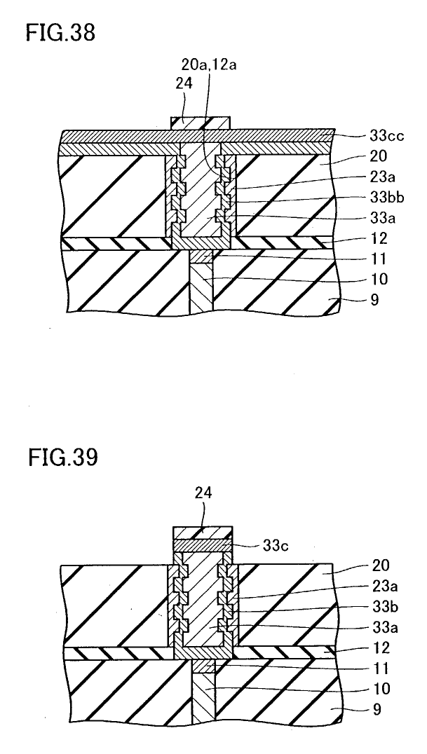

Next, as shown in FIG. 37, an outer conductive layer 33cc made of Ru, which becomes an outer conductor, is formed on semiconductor substrate 1. Next, as shown in FIG. 38, a resist pattern 24 is formed on this outer conductive layer 33cc.

Dry etching using an oxygen-based gas is carried out using the above described resist pattern 24 as a mask and, thereby, the portions of outer conductive layers 33cc and 33bb located on the top surface of silicon oxide film 20 are removed, as shown in FIG. 39.

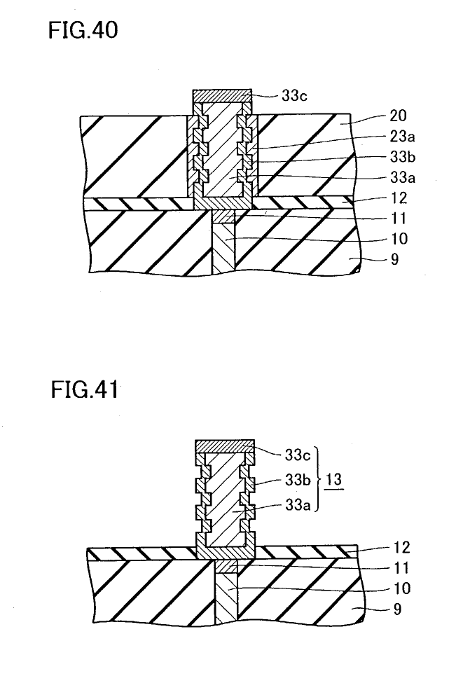

Next, as shown in FIG. 40, resist pattern 24 is removed. Next, wet etching is carried out using buffered hydrofluoric acid (BHF) and, thereby, silicon oxide film 20 is removed. After that, as shown in FIG. 41, wet etching is carried out using aqueous ammonia and, thereby, amorphous silicon film 23a having a roughened surface is removed.

Thereby, a storage node 13 is formed of inner conductor 33a as well as outer conductors 33b and 33c. The surface of outer conductor 33b, in particular, is uneven in this storage node 13.

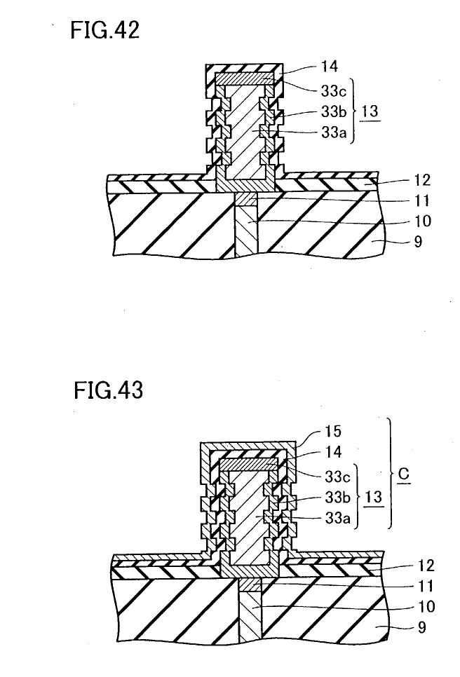

Next, as shown in FIG. 42, dielectric film 14, such as of Ta₂O₅, having a film thickness of from approximately 5 nm to 15 nm is formed on the surface of storage node 13.

Next, as shown in FIG. 43, cell plate 15, such as of a Ru film, having a film thickness of from approximately 40 nm to 80 nm is formed on dielectric film 14. Thereby, capacitor C is formed of storage node 13, dielectric film 14 and cell plate 15.

After that, a silicon oxide film that covers capacitor C, predetermined aluminum wires 17a, 17b, and the like, (see FIG. 1) are formed as described above so as to complete the semiconductor device provided with capacitor C.

According to the above described manufacturing method for a semiconductor device, amorphous silicon film 23a having a roughened surface is formed on the side surfaces of the opening formed in silicon oxide film 20 having a predetermined thickness and outer conductor 33b, such as of Ru, is formed on the surface of this amorphous silicon film 23a having a roughened surface.

Then, inner conductor 33a having a high adhesion to Ru is formed so as to fill in this opening. Furthermore, outer conductor 33c, such as of Ru, is formed so as to cover this inner conductor 33a.

Thereby, in the present semiconductor device, the desired height of storage node 13 is provided by inner conductor 33a, having a high adhesion to Ru, wherein outer conductors 33b and 33c, made of Ru, are formed on the side and top surfaces of this inner conductor 33a, in contrast to the prior art wherein increase in the height of the storage node by means of increase in the thickness of the metal film, such as of Ru, is limited due to the peeling off of the Ru film.

As a result, the height of storage node 13 can be increased without increasing the thickness of the metal film, such as of Ru, so that the capacitance of capacitor C can be secured.

Furthermore, outer conductor 33b is formed on the surface of amorphous silicon film 23a having a roughened surface and, thereby, the surface of outer conductor 33b becomes uneven and the surface area of capacitor C is increased so that the capacitance can be further increased.

In addition, comparatively thin Ru films are formed on the surfaces of inner conductor 33a as outer conductive layers 33bb and 33cc, which become the outer conductors and, thereby, outer conductors 33b and 33c can be prevented from peeling off and the yield of semiconductor devices is increased.

Furthermore, comparatively thin Ru films are formed as outer conductors 33b and 33c, and, thereby, increase in the production cost due to the usage of Ru films, which are expensive, can be avoided.

Furthermore, as described above, in the case wherein a storage node is formed by means of filling in the opening, there may be current leakage due to a recess formed in the top surface portion of the storage node.

According to the above described manufacturing method, outer conductor 33c is formed so as to cover the top surface of inner conductor 33a after the formation of inner conductor 33a and, therefore, in the case wherein a recess is formed in inner conductor 33a, this recess is covered with outer conductor 33c so that current leakage can be prevented.

### Ninth Embodiment

An example of a case is cited and described wherein outer conductor 33c, which covers the top surface of inner conductor 33a of the storage node, is formed by means of patterning using a resist pattern according to the above described manufacturing method. Here, a case is described wherein outer conductor 33c, which covers the top surface of inner conductor 33a, is formed using a so-called damascene method.

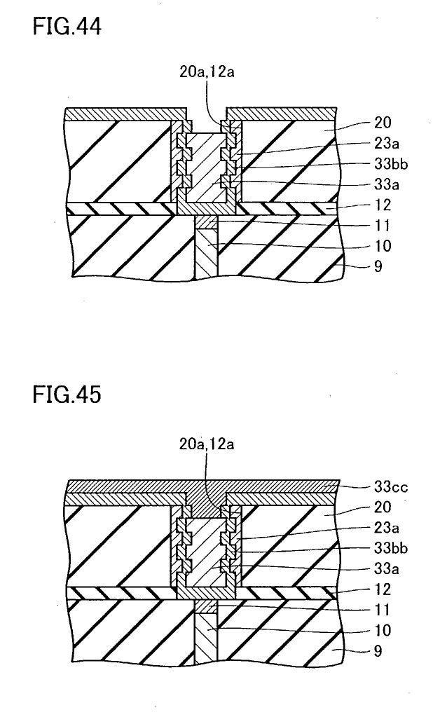

First, after the above described step shown in FIG. 35, dry etching is carried out under the condition wherein the etching selection ratio of inner conductive layer 33aa to outer conductive layer 33bb is comparatively high, using, for example, a chlorine-based gas (TiN, TaN) or a fluorine-based gas (WN) and, thereby, inner conductor 33a, of which the top surface is located at a position lower than the position of the top surface of silicon oxide film 20, is formed, as shown in FIG. 44.

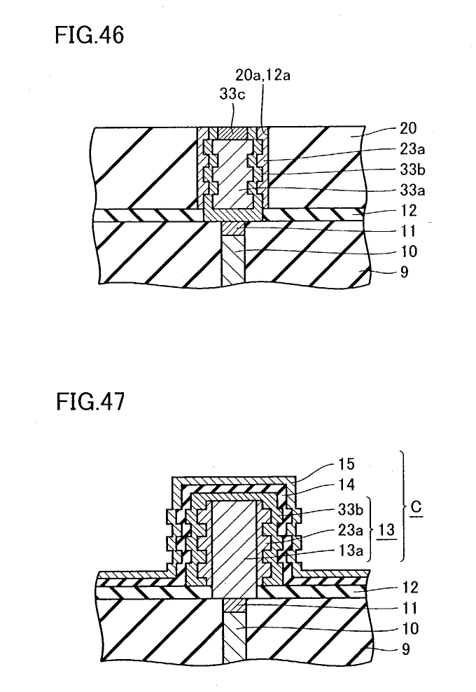

Next, as shown in FIG. 45, outer conductive layer 33cc, made of Ru, is formed so as to cover the top surface of inner conductor 33a within opening 20a,12a. Next, as shown in FIG. 46, a CMP process is carried out and, thereby, the portion of outer conductive layer 33cc located above the top surface of silicon oxide film 20 is removed.

Thereby, outer conductor 33c is formed on the top surface of inner conductor 33a within opening 20a. A method for forming outer conductor 33c in such a manner is referred to as a damascene method.

After that, essentially the same steps as the above described steps shown in FIGS. 39 to 43 are followed so as to complete the semiconductor device provided with a capacitor.

According to the above described manufacturing method for a semiconductor device, the following effects are gained in addition to the effects gained according to the above described manufacturing method.

That is to say, outer conductor 33c, which covers the top surface of inner conductor 33a of the storage node, is formed according to a damascene method and, thereby, the photomechanical process for forming outer conductor 33c becomes unnecessary and the number of steps can be reduced.

### Tenth Embodiment

The semiconductor device according to a tenth embodiment of the present invention is described. As shown in FIG. 47, storage node 13 in capacitor C of the present semiconductor device is formed of inner conductor 13a in a columnar form having side and top surfaces, of amorphous silicon film 23a having a roughened surface located on the side surfaces of inner conductor 13a and of outer conductor 33b, made of a material different from that of inner conductor 13a, located on the surface of amorphous silicon film 23 having a roughened surface and on the top surface of inner conductor 13a.

Outer conductor 33b is formed of a metal film, such as of Ru having a film thickness of from approximately 40 nm to 80 nm. The surface of the portion of outer conductor 33b located on the side surfaces of inner conductor 33a is uneven.

Inner conductor 13a is formed of a film having a high adhesion to the metal film, such as of Ru. A TiN film, a TaN film or a WN film, for example, is used as a film having a high adhesion to Ru, or the like.

Here, though the structures above and below capacitor C are not illustrated in FIG. 47, these portions of the present semiconductor device have essentially the same structures as those shown in FIG. 1.

Outer conductor 33b, made of a metal film such as Ru, is formed on the side and top surfaces of inner conductor 13a in the above described semiconductor device.

Thereby, in the present semiconductor device, the desired height of storage node 13 is provided by inner conductor 13a, having a high adhesion to Ru, wherein outer conductor 33b, made of Ru, is formed on the side and top surfaces of this inner conductor 13a, in contrast to the prior art wherein increase in the height of the storage node by means of increase in the thickness of the metal film, such as of Ru, is limited due to the peeling off of the Ru film.

As a result, the height of storage node 13 can be increased without increasing the thickness of the metal film, such as of Ru, so that the capacitance of capacitor C can be secured.

Moreover, the portion of outer conductor 33b located on the side surfaces of inner conductor 13a is formed with amorphous silicon film 23a having a roughened surface interposed therebetween and, thereby, the surface of the portion of outer conductor 33b is uneven. Thereby, the surface area of capacitor C is increased and the capacitance can be further increased.

In addition, a comparatively thin Ru film is formed on the surfaces of inner conductor 13a as outer conductor 33b and, thereby, outer conductor 33b can be prevented from peeling off and the yield of semiconductor devices is increased.

Furthermore, a comparatively thin Ru film is formed as outer conductor 33b and, thereby, increase in the production cost due to the usage of Ru film, which is expensive, can be avoided.

In addition, in the case wherein TiN is utilized as inner conductor 13a, TiN has a higher adhesion to the insulating film in comparison with the case wherein Ru forms outer conductor 13b, and the bottom surface of inner conductor 13a makes direct contact with the insulating film, such as silicon oxide film 9, and, thereby, capacitor C does not easily fall over, thus contributing to an increase in the yield of semiconductor devices.

Furthermore, as described below, in the case wherein TaN is utilized as inner conductor 13a, TaN effectively blocks oxygen and can prevent the diffusion of oxygen into storage node contact holes at the time of the oxidation process to Ta₂O₅ and, thereby, increase in the contact resistance between storage node 13 and plug 10 can be restricted.

In addition, inner conductor 13a effectively blocks oxygen in the above described manner and, therefore, the bottom surface of inner conductor 13a may make direct contact with plug 10 without forming barrier metal 11 within the storage node contact hole.

### Eleventh Embodiment

An example of a manufacturing method for the semiconductor device described in the tenth embodiment is described below as an eleventh embodiment of the present invention.

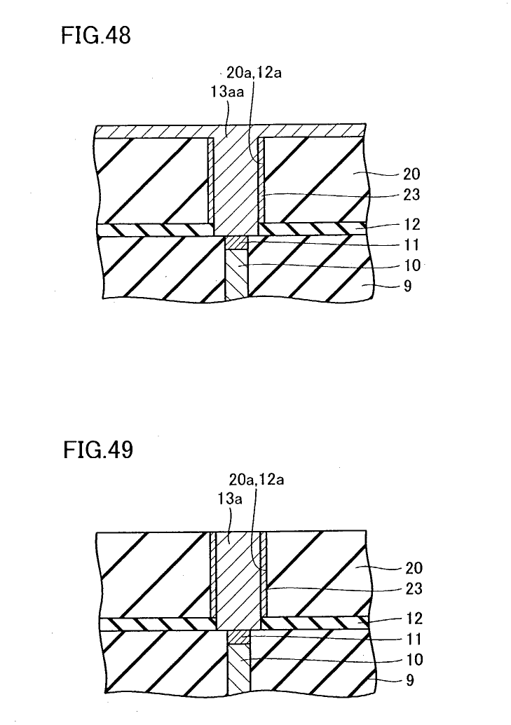

First, after the above described step shown in FIG. 32, inner conductive layer 13aa, which becomes an inner conductor having a film thickness of from approximately 80 nm to 120 nm, is formed on silicon oxide film 20 so as to fill in opening 20a, 12a, as shown in FIG. 48. A TiN film, a TaN film or a WN film, for example, having a high adhesion to Ru film, is formed as inner conductive layer 13aa.

Next, as shown in FIG. 49, dry etching using a chlorine-based gas in case of a TiN film and a TaN film or a fluorine-based gas in case of a WN film, for example, is carried out and, thereby, the portion of inner conductive layer 13aa located on the top surface of silicon oxide film 20 is removed so that inner conductor 13a is formed within opening 20a, 12a. Here, a CMP process may be carried out in order to form inner conductor 13a.

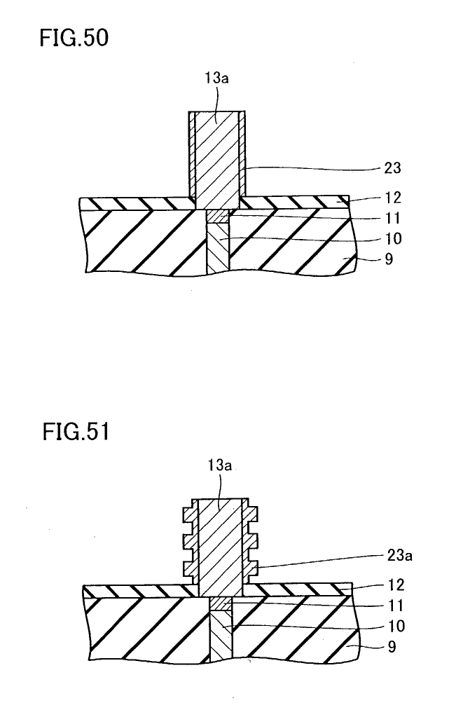

Next, as shown in FIG. 50, wet etching is carried out using buffered hydrofluoric acid (BHF) and, thereby, silicon oxide film 20 is removed so that amorphous silicon film 23 is exposed on the side surfaces of inner conductor 13a.

Next, as shown in FIG. 51, a surface roughening process is carried out on amorphous silicon film 23 so as to form amorphous silicon film 23a having a roughened surface.

Concretely, a heat treatment is carried out at a temperature of from approximately 500° C. to 750° C. while an Si₂H₆ gas is made to flow so that this temperature and a high vacuum are maintained and, thereby, unevenness is formed in the surface of amorphous silicon film 23 and amorphous silicon film 23a having a roughened surface is formed.

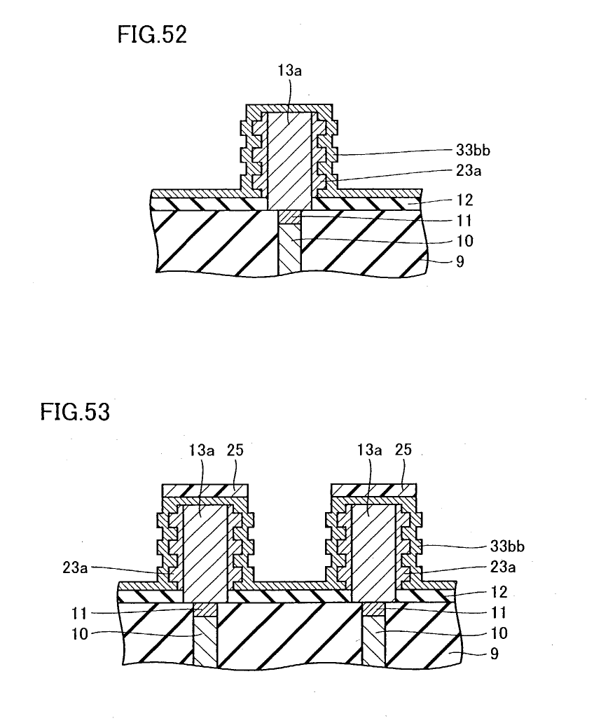

Next, as shown in FIG. 52, outer conductive layer 33bb, which becomes an outer conductor, is formed above semiconductor substrate 1 so as to cover the side and top surfaces of inner conductor 13a. At this time, outer conductive layer 33bb is formed on the side surfaces of inner conductor 13a with amorphous silicon film 23a having a roughened surface interposed therebetween and, thereby, the surface of outer conductive layer 33bb becomes uneven in this portion.

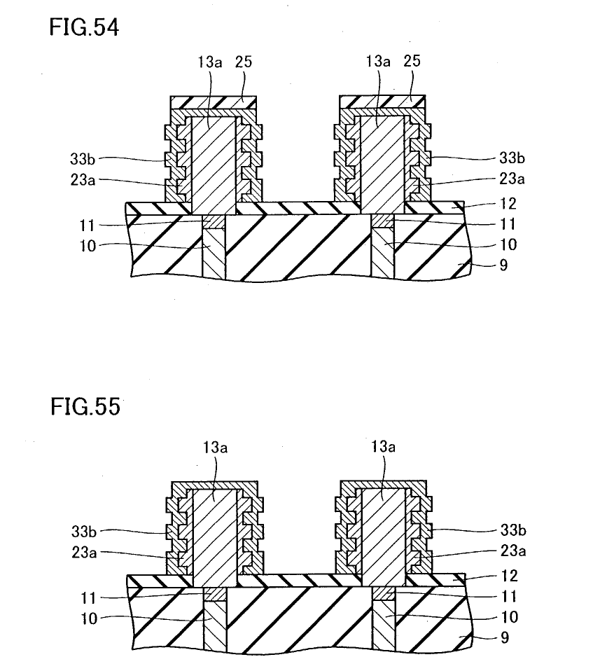

Next, as shown in FIG. 53, a resist pattern 25 is formed so as to cover the portion of outer conductive layer 33bb located on the top surface of inner conductor 13a. Next, as shown in FIG. 54, dry etching using an oxygen-based gas is carried out utilizing resist pattern 25 as a mask and, thereby, the portion of outer conductive layer 33bb located on the top surface of silicon nitride film 12 is removed.

The portion of outer conductive layer 33bb located between adjacent storage nodes is removed as a result of this etching process. After that, as shown in FIG. 55, resist pattern 25 is removed. Thereby, storage node 13 is formed of inner conductor 13a, amorphous silicon film 23a having a roughened surface and outer conductor 33b.

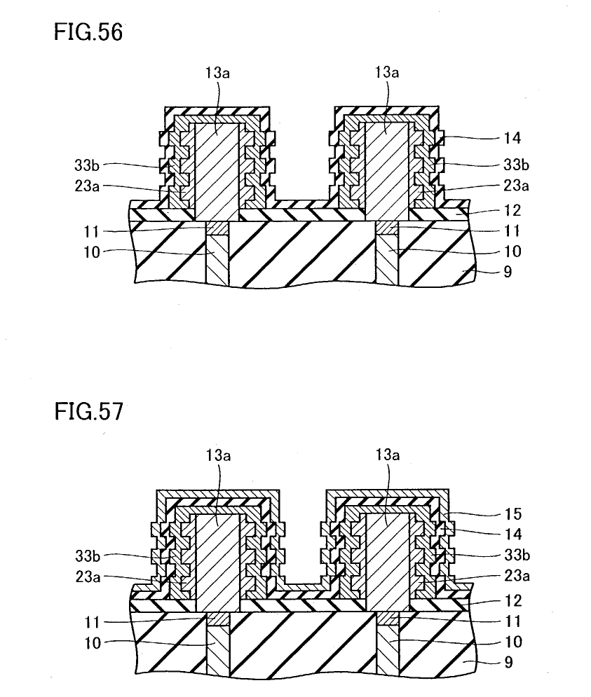

Next, as shown in FIG. 56, dielectric film 14, such as of Ta₂O₅ having a film thickness of from approximately 5 nm to 15 nm is formed on the surface of storage node 13. After that, an oxidation process is carried out on the Ta₂O₅ in order to increase the film quality of the Ta₂O₅.

Next, as shown in FIG. 57, cell plate 15, such as of Ru having a film thickness of from approximately 40 nm to 80 nm, is formed on dielectric film 14. Thereby, capacitor C is formed of storage node 13, dielectric film 14 and cell plate 15.

After that, a silicon oxide film that covers capacitor C, predetermined aluminum wires 17a, 17b, and the like, (see FIG. 1) are formed as described above so as to complete the semiconductor device provided with capacitor C.

According to the above described manufacturing method for a semiconductor device, inner conductor 13a is formed so as to fill in opening 20a formed in silicon oxide film 20 having a predetermined thickness. Then, outer conductor 33b is formed of a Ru film, or the like, so as to cover the side and top surfaces of inner conductor 13a that has been exposed after the removal of silicon oxide film 20.

Thereby, in the present semiconductor device, the desired height of storage node 13 is provided by inner conductor 13a, having a high adhesion to Ru, wherein outer conductor 33b, made of Ru, is formed on the side and top surfaces of this inner conductor 13a, in contrast to the prior art wherein increase in the height of the storage node by means of increase in the thickness of the metal film, such as of Ru, is limited due to the peeling off of the Ru film.

As a result, the height of storage node 13 can be increased without increasing the thickness of the metal film, such as of Ru, so that the capacitance of capacitor C can be secured.

Moreover, amorphous silicon film 23a having a roughened surface is formed on the side surfaces of inner conductor 13a and, thereby, the surface of outer conductor 33a formed on this portion becomes uneven. Thereby, the surface area of the capacitor is increased and the capacitance of the capacitor is further increased.

In addition, a comparatively thin Ru film is formed as outer conductive layer 33bb, which becomes the outer conductor and, thereby, increase in the production cost due to the usage of Ru film, which is expensive, can be avoided.

Furthermore, in the case wherein TiN is utilized as inner conductor 13a, TiN has a higher adhesion to the insulating film in comparison with the case wherein Ru forms outer conductor 13b, and the bottom surface of inner conductor 13a makes direct contact with the insulating film, such as silicon oxide film 9, and, thereby, capacitor C does not easily fall over, thus contributing to an increase in the yield of semiconductor devices.

In addition, a comparatively thin Ru film is formed on the surfaces of inner conductor 13a as outer conductive layer 33bb, which becomes the outer conductor and, thereby, outer conductor 33b can be prevented from peeling off, thus contributing to an increase in the yield of semiconductor devices.

Furthermore, as described above, TaN having characteristics wherein oxygen diffusion is effectively blocked is utilized for inner conductor 13a, which is formed so that the bottom surface of this inner conductor 13a covers the opening of the storage node contact hole.

Thereby, the diffusion of oxygen for the oxidation process, which is carried out on the Ta₂O₅, is blocked by the storage node 13 portions and, therefore, oxidation is prevented from reaching to plugs 10 within the storage node contact holes. As a result, increase in the contact resistance between storage nodes 13 and plugs 10 can be prevented.

In addition, inner conductors 13a, themselves, effectively block oxygen and, therefore, the formation of barrier metal 11 within the storage node contact holes can be omitted so that the number of steps can be reduced.

Furthermore, as described above, in the case wherein storage nodes are formed by means of filling in the openings, there may be current leakage due to recesses formed in the top surface portions of the storage nodes.

According to the above described manufacturing method, outer conductors 33b are formed so as to cover the top surfaces of inner conductors 13a after the formation of inner conductors 13a and, therefore, in the case wherein recesses are formed in inner conductors 13a, these recesses are covered with outer conductors 33b so that current leakage can be prevented.

### Twelfth Embodiment

An example of a case is cited and described according to the above described manufacturing method wherein the portion of outer conductive layer 33bb, which become outer conductors, located between adjacent storage nodes is removed by carrying out predetermined etching using resist pattern 25 covering the portion of outer conductive layer 33bb, located on the top surface of inner conductor 13a as a mask.

Here, an example of a case wherein the above described portion is removed by using the difference in the film thickness between the portions of the outer conductive layer formed by utilizing the step of inner conductor 13a itself, without forming a resist pattern, is cited and described.

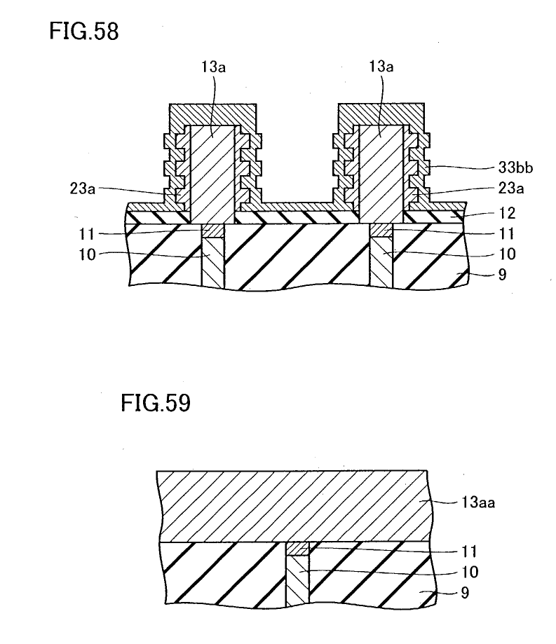

First, after the above described step shown in FIG. 51, outer conductive layer 33bb, which becomes outer conductors, is formed so as to cover inner conductors 13a and amorphous silicon films 23a having roughened surfaces as shown in FIG. 58.

At this time, outer conductive layer 33bb has a comparatively great film thickness in the portions on the top surfaces of inner conductors 13a while outer conductive layer 33bb has a comparatively small film thickness on silicon nitride film 12, located at the base of inner conductors 13a, because of the steps of inner conductors 13a.

That is to say, outer conductive layer 33bb is formed having a poor coverage over inner conductors 13a because of the steps of inner conductors 13a.

After that, etching is carried out on the entire surface of outer conductive layer 33bb and the etching is stopped at the point in time when the portions of outer conductive layer 33bb located on the top surfaces of silicon nitride film 12 have been removed.

Thereby, some portions of outer conductive layer 33bb remain unetched on the top surfaces of inner conductors 13a wherein the portions of outer conductive layer 33bb are thicker than the portions of outer conductive layer 33bb located on the top surfaces of silicon nitride film 12.

That is to say, the same state as the state described above in FIG. 55 is gained wherein the portion of outer conductive layer 33bb, located between adjacent storage nodes, is removed in a self-aligning manner so that the portion of outer conductive layer 33bb located on the top surface of inner conductor 13a remains.

After that, essentially the same steps as the above described steps shown in FIGS. 56 and 57 are followed so as to complete the semiconductor device provided with a capacitor.

According to the above described manufacturing method for a semiconductor device, the following effects are gained in addition to the effects gained according to the above described manufacturing method.

That is to say, the portion of outer conductive layer 33bb located between adjacent storage nodes is removed in a self-aligning manner and, thereby, the photomechanical process for removing this portion becomes unnecessary and the number of steps can be reduced.

### Thirteenth Embodiment

An example of a case wherein a storage node is formed within the opening formed in a silicon oxide film is cited and described in the fifth and sixth embodiments, wherein manufacturing methods for the semiconductor device according to the fourth embodiment are described.

Here, an example of a case is cited and described wherein the storage node is formed without forming an opening as still another manufacturing method for the semiconductor device described in the fourth embodiment.

First, as shown in FIG. 59, inner conductive layer 13aa, which becomes an inner conductor, having a film thickness of from approximately 1000 nm to 1500 nm is formed on silicon oxide film 9. A TiN film, a TaN film or a WN film, for example, having a high adhesion to Ru film is formed as inner conductive layer 13aa.

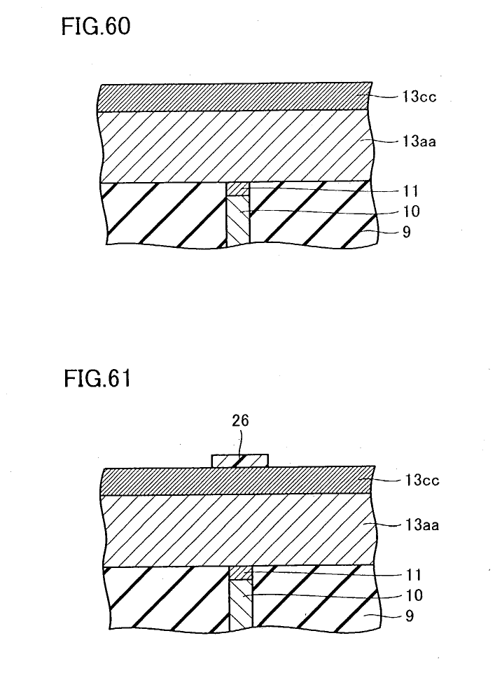

Next, as shown in FIG. 60, outer conductive layer 13cc, which becomes an outer conductor made of Ru, having a film thickness of from approximately 40 nm to 80 nm is formed of a material different from that of inner conductive layer 13aa on the above described inner conductive layer 13aa.

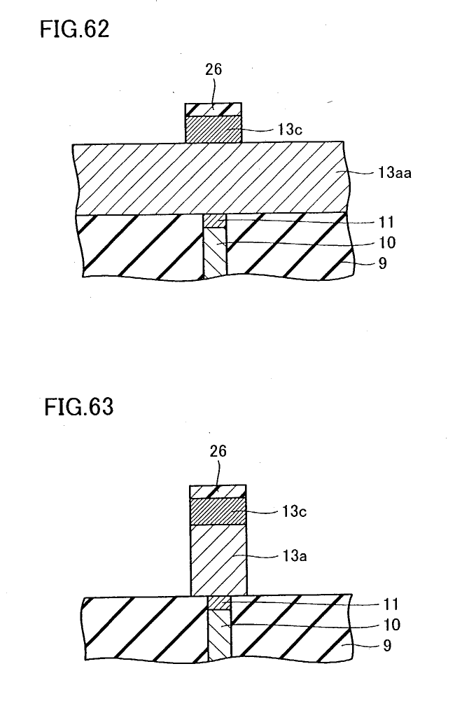

Next, as shown in FIG. 61, a resist pattern 26 is formed so as to cover a predetermined region in outer conductive layer 13cc wherein the storage node is to be provided. Next, as shown in FIG. 62, dry etching using an oxygen-based gas is carried out utilizing resist pattern 26 as a mask and, thereby, the outer conductive layer 13cc portion, except for the portion located directly above the storage node contact hole, is removed.

Furthermore, as shown in FIG. 63, dry etching using a chlorine-based gas (TiN, TaN) or a fluorine-based gas (WN) is carried out utilizing resist pattern 26 as a mask and, thereby, the inner conductive layer 13aa portion, except for the portion located directly above the storage node contact hole, is removed.

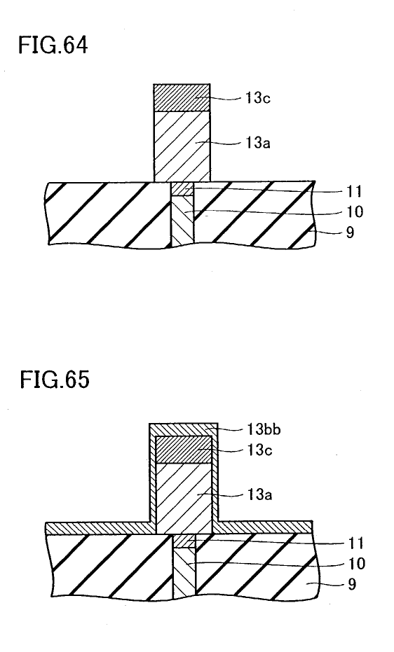

Thereby, inner conductor 13a and outer conductor 13c, which covers the top surface of this inner conductor 13a, are formed. After that, as shown in FIG. 64, resist pattern 26 is removed.

Next, as shown in FIG. 65, outer conductive layer 13bb, which becomes another outer conductor, is formed in semiconductor substrate 1 so as to cover inner conductor 13a and outer conductor 13c.

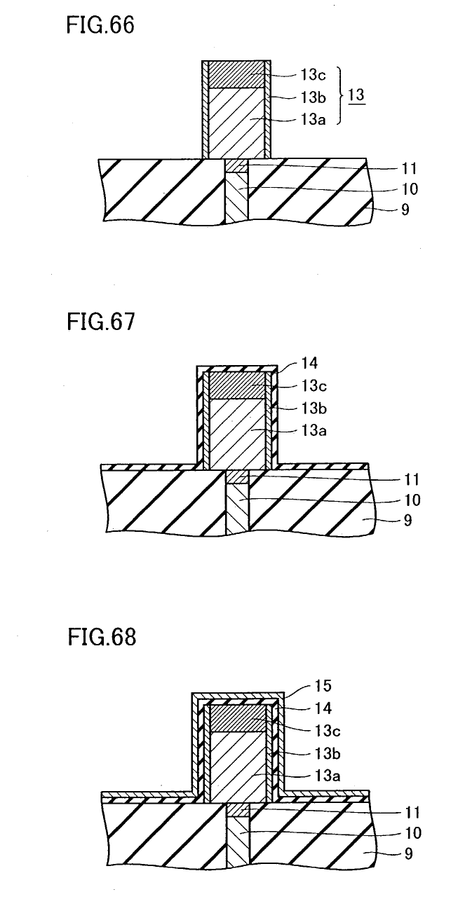

Next, as shown in FIG. 66, etching is carried out on the entire surface of outer conductive layer 13bb and the etching is stopped at the point in time when the portion of outer conductive layer 13bb located on the top surface of silicon oxide film 9 has been removed.

Thereby, etching is not carried out on the portion of outer conductive layer 13cc located on the top surface of silicon oxide film 9 and the state is gained wherein outer conductive layer 13cc remains as outer conductor 13c. Thereby, storage node 13 is formed of inner conductor 13a as well as outer conductors 13b and 13c.

Next, as shown in FIG. 67, dielectric film 14, such as of Ta₂O₅ having a film thickness of from approximately 5 nm to 15 nm is formed on the surface of storage node 13. Next, as shown in FIG. 68, cell plate 15, such as of Ru film, having a film thickness of from approximately 40 nm to 80 nm is formed on dielectric film 14. Thereby, capacitor C is formed of storage node 13, dielectric film 14 and cell plate 15.

After that, as described above, a silicon oxide film that covers capacitor C, predetermined aluminum wires 17a, 17b, and the like, (see FIG. 1), are formed so as to complete the semiconductor device provided with capacitor C.

According to the above described manufacturing method for a semiconductor device, the following effects are gained in the same manner as in the manufacturing method described in the sixth embodiment, in addition to the effects gained according to the manufacturing method described in the fifth embodiment. That is to say, the photomechanical process for removing the portion of outer conductive layer 13bb, which becomes the outer conductor, positioned between adjacent storage nodes becomes unnecessary and the number of steps can be reduced.

Here, in the respective above described embodiments, TiN, TaN, WN, or the like, for the inner conductor, Ru for the outer conductor and Ta₂O₅ for the dielectric film, respectively, are cited as examples and are described.

Though the material for the outer conductor is selected so that the outer conductor has characteristics, in regard to the dielectric film, that increase the dielectric constant of the dielectric film, the outer conductor tends to easily peel off when formed so as to have a comparatively great thickness, while the material for the inner conductor is not limited to the above described materials, as long as the inner conductor has characteristics that allow adhesion of the outer conductor to the inner conductor as described above.

As described above, in the semiconductor devices described in the first, fourth, seventh and tenth embodiments, the first electrode, as the storage node, is provided with an inner conductor and an outer conductor. The inner conductor is formed on the main surface of a semiconductor substrate and has bottom, side and top surfaces. The outer conductor is formed on the side and top surfaces, respectively, of the inner conductor and is formed of a material that has peeling characteristics vis-à-vis the base that differ from the peeling characteristics of the inner conductor vis-à-vis the base.

Thereby, in the present semiconductor device, the desired height of the first electrode is provided by the inner conductor wherein a comparatively thin outer conductor is formed on the side and top surfaces of this inner conductor, in contrast to the prior art wherein increase in the height of the storage node by means of increase in the thickness of the outer conductive layer, which forms the outer conductor, is limited due to the peeling off of this outer conductive layer. Thereby, the height of the first electrode can be increased without increasing the thickness of the outer conductive layer so that the capacitance of capacitor C can be secured.

In the second, third, eighth and ninth embodiments, first, outer first conductive layer is formed in the opening formed in the silicon oxide film and, then, an inner conductive layer is formed on the outer first conductive layer so as to fill in this opening. After that, an outer second conductive layer is formed on the top surface of this inner conductive layer. Thereby, the state is gained wherein the inner conductor is formed of the inner conductive layer, wherein a portion of the outer conductor is formed of the outer first conductive layer on the side surfaces of this inner conductor and wherein another portion of the outer conductor is formed of the outer second conductive layer on the top surface of the inner conductor.

In addition, in the fifth, sixth, eleventh, twelfth and thirteenth embodiments, first, the inner conductor is formed and, then, the outer conductive layer is formed on the side and top surfaces of this inner conductor and, thereby, the outer conductor is formed.

Thereby, the desired height of the storage node (first electrode) is provided by the inner conductor in all cases wherein a comparatively thin outer conductor is formed on the side and top surfaces of this inner conductor. As a result, the height of the first electrode can be increased without increasing the thickness of the outer conductor so that the capacitance of capacitor C can be obtained.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising a capacitor having a dielectric film interposed between a first electrode and a second electrode, wherein
said first electrode includes:
an inner conductor, formed on a main surface of a semiconductor substrate, having bottom, side and top surfaces; and
an outer conductor, formed on said side surface and said top surface of said inner conductor, respectively, having a different material from that of said inner conductor.

2. The semiconductor device according to claim 1, wherein
said outer conductor is formed in a portion located between said semiconductor substrate and the bottom surface of said inner conductor.

3. The semiconductor device according to claim 2, wherein
the portion, formed on the side surface of said inner conductor, in said outer conductor has an uneven surface.

4. The semiconductor device according to claim 1, wherein
the portion, formed on the side surfaces of said inner conductor, in said outer conductor has an uneven surface.

5. A manufacturing method for a semiconductor device, comprising the steps of:
forming a first electrode including an inner conductor and an outer conductor; and
forming a second electrode with a dielectric film interposed on said first electrode, wherein
said step of forming a first electrode includes the steps of:
forming an insulating film on a semiconductor substrate;
forming an opening having a predetermined depth in said insulating film;
forming an outer first conductive layer, functioning as said outer conductor, so as to cover the bottom and side surfaces of said opening;
forming an inner conductive layer, having a different material from that of said outer first conductive layer and functioning as said inner conductor, on said outer first conductive layer within said opening;
covering the top surface of said inner conductive layer with an outer second conductive layer having substantially the same material as that of said outer first conductive layer and functioning as said outer conductor; and
removing said insulating film to expose surfaces of said outer first conductive layer and of said outer second conductive layer.

6. The manufacturing method for a semiconductor device according to claim 5, wherein
said step of covering the top surface of said inner conductive layer with said outer second conductive layer includes the steps of:
forming said outer second conductive layer on said insulating film so as to cover said inner conductive layer; and
forming a predetermined resist pattern on said outer second conductive layer and performing etching on said outer second conductive layer using said resist pattern as a mask, thereby removing the portion of said outer second conductive layer located on the top surface of said insulating film and leaving the portion of said outer second conductive layer located on the top surface of said inner conductive layer.

7. The manufacturing method for a semiconductor device according to claim 6, wherein
the method comprises the step of covering the side surfaces of said opening with a predetermined uneven film after forming said opening and before forming said outer first conductive layer,
said outer first conductive layer is formed so as to cover said predetermined film in said step of forming said outer first conductive layer, and
the method comprises the step of removing said predetermined film after removing said insulating film and before forming said dielectric film.

8. The manufacturing method for a semiconductor device according to claim 5, wherein
said step of forming said inner conductive layer includes the step of forming said inner conductive layer so that the top surface of said inner conductive layer within said opening is lower than the top surface of said insulating film, and
said step of covering the top surface of said inner conductive layer with said outer second conductive layer includes the steps of:
forming said outer second conductive layer on said insulating film so as to bury said inner conductive layer within said opening; and
removing the portion of said outer second conductive layer located on said insulating film to leave the portion of said outer second conductive layer located on the top surface of said inner conductive layer within said opening.

9. The manufacturing method for a semiconductor device according to claim 8, wherein
the method comprises the step of covering the side surfaces of said opening with a predetermined uneven film after forming said opening and before forming said outer first conductive layer,
said outer first conductive layer is formed so as to cover said predetermined film in said step of forming said outer first conductive layer, and
the method comprises the step of removing said predetermined film after removing said insulating film and before forming said dielectric film.

10. A manufacturing method for a semiconductor device, comprising the steps of:
forming a first electrode including an inner conductor and an outer conductor; and
forming a second electrode with a dielectric film interposed on said first electrode, wherein
said step of forming said first electrode includes the steps of:
forming said inner conductor having an inner conductive layer having side and top surfaces on a semiconductor substrate; and
forming an outer conductive layer, having a different material from that of said inner conductive layer and functioning as said outer conductor, so as to cover said inner conductor.

11. The manufacturing method for a semiconductor device according to claim 10, wherein
said step of forming said inner conductor includes the steps of:
forming an insulating film on said semiconductor substrate;
forming an opening in said insulating film;
forming said inner conductive layer within said opening; and
removing said insulating film to expose the side and top surfaces of said inner conductive layer.

12. The manufacturing method for a semiconductor device according to claim 11, wherein
said step of forming said outer conductive layer includes the steps of:
forming said outer conductive layer so as to cover said inner conductor;
forming a resist pattern for covering the portion of said outer conductive layer located on the top surface of said inner conductor; and
performing etching on said outer conductive layer using said resist pattern as a mask, thereby leaving the portion of said outer conductive layer located on the top and side surfaces of said inner conductor remains and removing the remaining portion in said outer conductor.

13. The manufacturing method for a semiconductor device according to claim 12, wherein
the method comprises the step of forming a predetermined uneven conductive film on a surface of said inner conductor after forming said inner conductor and before forming said outer conductive layer, and
said outer conductive layer is formed on said predetermined conductive film in said step of forming said outer conductive layer.

14. The manufacturing method for a semiconductor device according to claim 11, wherein
said step of forming said outer conductive layer includes the steps of:
forming said outer conductive layer, covering said inner conductor, so that the film thickness of the portion formed on the top surface of said inner conductor is greater than the film thickness of the portion formed beneath the top surface of said inner conductor, by utilizing a step of said inner conductor itself; and
performing a process on said outer conductive layer, thereby leaving the portion of said outer conductive layer located on the top surface of said inner conductor remains and removing the remaining portion of said outer conductive layer.

15. The manufacturing method for a semiconductor device according to claim 14, wherein
the method comprises the step of forming a predetermined uneven conductive film on a surface of said inner conductor after forming said inner conductor and before forming said outer conductive layer, and
said outer conductive layer is formed on said predetermined conductive film in said step of forming said outer conductive layer.

16. The manufacturing method for a semiconductor device according to claim 10, wherein
said step of forming said inner conductor includes the steps of:
forming said inner conductive layer on said semiconductor substrate; and
performing a predetermined process on said inner conductive layer, thereby leaving the portion located on a predetermined region in which said first electrode is provided and removing the portion located in the other region to expose the side and top surface of said inner conductive layer.
